(19) United States
(12) Patent Application Publication
(10) Pub. No.: US 2025/0359429 A1
(43) Pub. Date: Nov. 20, 2025

(54) METHOD OF MANUFACTURING A DISPLAY DEVICE AND ELECTRONIC DEVICE INCLUDING THE DISPLAY DEVICE

(71) Applicant: Samsung Display Co., LTD., Yongin-si (KR)

(72) Inventors: Yun-Mo CHUNG, Yongin-si (KR); Daewoo LEE, Yongin-si (KR); Ji-Sil LEE, Yongin-si (KR)

(73) Assignee: Samsung Display Co., LTD., Yongin-si (KR)

(21) Appl. No.: 19/012,549

(22) Filed: Jan. 7, 2025

(30) Foreign Application Priority Data
May 14, 2024 (KR) 10-2024-0063171

(51) Int. Cl. H10K 59/12; H10K 59/80

(52) U.S. Cl. CPC H10K 59/1201; H10K 59/873

(57) ABSTRACT

A method of manufacturing a display device includes forming a transistor on a substrate including a display area and a non-display area surrounding at least a portion of the display area, forming a first conductive layer in the non-display area on the substrate, forming a first insulating layer covering the first conductive layer and the transistor, forming a protecting insulating layer at least partially overlapping the first conductive layer on the first insulating layer, forming a second insulating layer at least partially overlapping the transistor on the first insulating layer, removing the second portion of the protecting insulating layer, forming a first electrode connected to the transistor on the second insulating layer, forming a pixel defining layer covering a side portion of the first electrode on the second insulating layer, forming a light emitting layer on the first electrode, and forming a second electrode on the light emitting layer.

### CROSS-REFERENCE TO RELATED APPLICATION(S)

This application claims priority to and benefits of Korean Patent Application No. 10-2024-0063171 under 35 U.S.C. § 119, filed on May 14, 2024, in the Korean Intellectual Property Office (KIPO), the entire contents of which are incorporated herein by reference.

### BACKGROUND

### 1. Technical Field

Embodiments relate to a method of manufacturing a display device providing visual information, and an electronic device including the display device.

### 2. Description of the Related Art

A display device is a device that displays an image for providing visual information to a user. Among display devices, an organic light emitting diode display device has recently attracted attention.

The display device may include a driver such as a gate driver, a data driver, and the like. The gate driver may include multiple wirings to which a clock signal or the like is applied. When moisture and the like penetrates into the insulating layer covering the wirings, the clock signal or the like may be applied to the wirings with delay.

### SUMMARY

Embodiments provide a method of manufacturing a display device with improved quality.

Embodiments provide an electronic device including the display device.

A method of manufacturing a display device according to an embodiment may include forming a transistor on a substrate including a display area and a non-display area surrounding at least a portion of the display area, forming a first conductive layer in the non-display area on the substrate, forming a first insulating layer covering the first conductive layer and the transistor, forming a protecting insulating layer at least partially overlapping the first conductive layer in a plan view on the first insulating layer, the protecting insulating layer including a first portion and a second portion having a thickness smaller than a thickness of the first portion, forming a second insulating layer at least partially overlapping the transistor in a plan view on the first insulating layer, removing a second portion of the protecting insulating layer, forming a first electrode connected to the transistor on the second insulating layer, forming a pixel defining layer covering a side portion of the first electrode on the second insulating layer, forming a light emitting layer on the first electrode, and forming a second electrode on the light emitting layer.

In an embodiment, the protecting insulating layer may include a first portion and the second portion having a thickness smaller than a thickness of the first portion.

In an embodiment, the removing of the second portion of the protecting insulating layer may be performed through a plasma ashing process.

In an embodiment, the method may further include forming a preliminary dam in the non-display area on the first insulating layer.

In an embodiment, the forming of the protecting insulating layer and the forming of the preliminary dam may be performed simultaneously.

In an embodiment, the first conductive layer may be disposed in a gate driver disposed in the non-display area on the substrate.

In an embodiment, a clock signal may be applied through the first conductive layer.

In an embodiment, the method may further include forming a second conductive layer spaced apart from the first conductive layer in a plan view in the non-display area on the substrate, the first conductive layer and the second conductive layer disposed on a same layer, and the second conductive layer applied with a clock signal.

In an embodiment, the method may further include performing plasma treatment on the first insulating layer after the removing of the second portion of the protecting insulating layer.

In an embodiment, the performing of plasma treatment on the first insulating layer may be performing nitrogen (N₂) plasma treatment on the first insulating layer.

In an embodiment, through the removing of the second portion of the protecting insulating layer, a thickness of the first portion of the protecting insulating layer may be reduced.

In an embodiment, the method may further include forming a third insulating layer on the first portion of the protecting insulating layer with a reduced thickness to form a support part including the first portion with the reduced thickness and the third insulating layer.

In an embodiment, the non-display area may include a pad area.

In an embodiment, the method may further include forming a first auxiliary pad electrode in the pad area on the substrate and forming a second auxiliary pad electrode on the first auxiliary pad electrode.

In an embodiment, the forming of the first insulating layer may include forming a first preliminary insulating layer covering the second auxiliary pad electrode and forming a first opening exposing an upper surface of the second auxiliary pad electrode in the first preliminary insulating layer.

In an embodiment, the forming of the first opening in the first preliminary insulating layer may include forming a second preliminary insulating layer on the first preliminary insulating layer, forming a second opening overlapping the second auxiliary pad electrode in a plan view in the second preliminary insulating layer, and forming the first opening overlapping the second opening in a plan view in the first preliminary insulating layer.

In an embodiment, the method may further include removing at least a portion of the second preliminary insulating layer after the forming of the first opening.

A method of manufacturing a display device according to an embodiment may include forming a transistor on a substrate including a display area and a non-display area surrounding at least a portion of the display area, forming a conductive layer in the non-display area on the substrate, forming a passivation layer covering the conductive layer and the transistor, forming a protecting insulating layer at least partially overlapping the conductive layer in a plan view on the passivation layer, the protecting insulating layer include a first portion and a second portion having a thickness smaller than a thickness of the first portion, forming a via insulating layer at least partially overlapping the transistor in a plan view on the passivation layer, removing a second portion of the protecting insulating layer, forming a pixel electrode connected to the transistor on the via insulating layer, forming a pixel defining layer covering a side portion of the pixel electrode on the via insulating layer, forming a light emitting layer on the pixel electrode, and forming a common electrode on the light emitting layer.

In an embodiment, the protecting insulating layer may include a first portion and the second portion having a thickness smaller than a thickness of the first portion.

In an embodiment, the removing of the second portion of the protecting insulating layer may be performed through a plasma ashing process.

In an embodiment, the method may further include forming a preliminary dam in the non-display area on the passivation layer.

In an embodiment, the forming of the protecting insulating layer and the forming of the preliminary dam may be performed simultaneously.

In an embodiment, the conductive layer may be disposed in a gate driver disposed in the non-display area on the substrate.

In an embodiment, a clock signal may be applied through the conductive layer.

In an embodiment, the method may further include performing plasma treatment on the passivation layer after the removing of the second portion of the protecting insulating layer.

An electronic device according to an embodiment may include a display device and a memory device configured to store data.

In an embodiment, a method of manufacturing the display device may include forming a transistor on a substrate including a display area and a non-display area surrounding at least a portion of the display area, forming a first conductive layer in the non-display area on the substrate, forming a first insulating layer covering the first conductive layer and the transistor, forming a protecting insulating layer at least partially overlapping the first conductive layer in a plan view on the first insulating layer, the protecting insulating layer including a first portion and a second portion having a thickness smaller than a thickness of the first portion, forming a second insulating layer at least partially overlapping the transistor in a plan view on the first insulating layer, removing a second portion of the protecting insulating layer, forming a first electrode connected to the transistor on the second insulating layer, forming a pixel defining layer covering a side portion of the first electrode on the second insulating layer, forming a light emitting layer on the first electrode, and forming a second electrode on the light emitting layer.

A method of manufacturing a display device according to an embodiment may include forming a first conductive layer in the non-display area on the substrate, forming a first insulating layer covering the first conductive layer and the transistor, forming a protecting insulating layer at least partially overlapping the first conductive layer in a plan view on the first insulating layer, removing a second portion of the protecting insulating layer. The protecting insulating layer may include a first portion and the second portion having a thickness smaller than a thickness of the first portion. The removing of the second portion of the protecting insulating layer may be performed through a plasma ashing process. The conductive layer may be disposed in a gate driver.

As the protecting insulating layer is formed on the first insulating layer, moisture or the like may not penetrate into the first insulating layer during the plasma ashing process. Accordingly, parasitic capacitance may be prevented from being generated in vicinity of the first conductive layer. Accordingly, a phenomenon in which signal is applied to the first conductive layer with delay may be prevented, and the gate driver may output a normal signal to the display area.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is a schematic block diagram illustrating a display device of FIG. 1.

FIG. 3 is a schematic diagram of an equivalent circuit illustrating a circuit structure of a pixel included in the display device of FIG. 1.

FIG. 4 is a schematic diagram illustrating a gate driver included in the display device of FIG. 1.

FIG. 5 is a schematic cross-sectional view of the display device of FIG. 1 taken along line I-I′.

FIG. 6 is a schematic cross-sectional view of the display device of FIG. 1 taken along line II-II′.

FIGS. 7, 8, 9, 10, 11, 12, 13, 14, 15, 16, 17, 18, 19, 20, 21, 22, 23, and 24 are schematic cross-sectional views illustrating a method of manufacturing the display device of FIG. 1.

FIG. 25 is a block diagram illustrating an electronic device according to embodiments.

FIG. 26 is a diagram illustrating an example in which the electronic device of FIG. 25 is implemented as a smart phone.

### DETAILED DESCRIPTION OF THE EMBODIMENTS

Hereinafter, display devices in accordance with embodiments will be described in more detail with reference to the accompanying drawings. The same reference numerals are used for the same components in the drawings, and redundant descriptions of the same components will be omitted.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

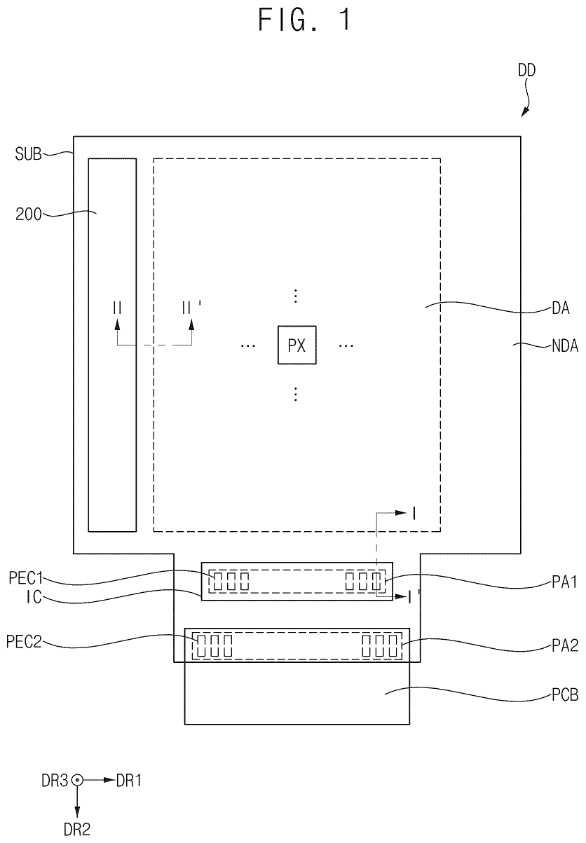

FIG. 1 is a plan view illustrating a display device according to an embodiment.

Referring to FIG. 1, a display device DD according to an embodiment may include a display area DA and a non-display area NDA. The display area DA may be an area for displaying an image by generating light or adjusting a transmittance of light provided from an external light source.

The non-display area NDA may be disposed adjacent to the display area DA. For example, the non-display area NDA may surround at least a portion of the display area DA in a plan view. In an embodiment, the non-display area NDA may be an area that does not display an image. However, this disclosure is not limited thereto, and in another embodiment, an image may be displayed in at least a portion of the non-display area NDA. For example, a light emitting element that emits light may be disposed in at least a portion of the non-display area NDA.

In an embodiment, the non-display area NDA may include a pad area. For example, the non-display area NDA may include a first pad area PA1 and a second pad area PA2. The first pad area PA1 may be spaced apart from a side of the display area DA in a second direction DR2. The second pad area PA2 may be spaced apart from the first pad area PA1 in the second direction DR2.

The display device DD may include a substrate SUB. The substrate SUB may form a base of the display device DD. As the display device DD includes the display area DA and the non-display area NDA including the first pad area PA1 and the second pad area PA2, the substrate SUB may also include a display area DA and a non-display area NDA including the first pad area PA1 and the second pad area PA2.

Multiple pixels PX may be disposed on the substrate SUB. The pixels PX may be disposed in the display area DA. The pixels PX may emit light based on a signal applied from the non-display area NDA. The pixels PX may be repeatedly arranged in a first direction DR1 and the second direction DR2 intersecting the first direction DR1. Accordingly, the display area DA may emit light over entire area and display an image.

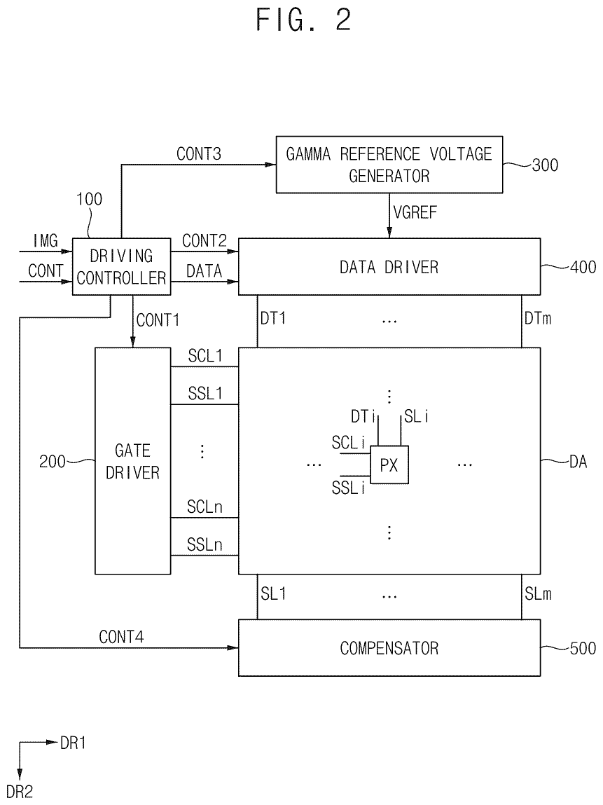

Multiple drivers for driving the pixels PX may be disposed on the substrate SUB. The drivers may be disposed in the non-display area NDA. For example, a gate driver 200, a data driver (e.g., a data driver 400 of FIG. 2), a compensator (e.g., a compensator 500 of FIG. 2), and the like may be disposed in the non-display area NDA on the substrate SUB. For convenience of description, only the gate driver 200 among the drivers is illustrated in FIG. 1.

Multiple first pad electrodes PEC1 may be disposed on the substrate SUB. The first pad electrodes PEC1 may be disposed in the first pad area PA1. The first pad electrodes PEC1 may be repeatedly arranged in the first direction DR1.

A driving chip IC may be disposed on the substrate SUB. The driving chip IC may at least partially overlap the first pad area PA1 in a plan view. For example, the driving chip IC may be electrically connected to the first pad electrodes PEC1. The driving chip IC may convert a digital data signal of driving signals into an analog data signal. The driving chip IC may provide the data signal to the pixels PX through the first pad electrodes PEC1.

Multiple second pad electrodes PEC2 may be disposed on the substrate SUB. The second pad electrodes PEC2 may be disposed in the second pad area PA2. The second pad electrodes PEC2 may be repeatedly arranged in the first direction DR1.

A circuit board PCB may be disposed on the substrate SUB. The circuit board PCB may at least partially overlap the second pad area PA2 in a plan view. For example, the circuit board PCB may be electrically connected to the second pad electrodes PEC2. The circuit board PCB may apply a driving signal, a driving voltage, and the like to the driving chip IC and the pixels PX through the second pad electrodes PEC2.

In an embodiment, the first direction DR1 and the second direction DR2 intersecting the first direction DR1 may be defined. For example, the second direction DR2 may be perpendicular to the first direction DR1. However, this disclosure is not limited thereto, and the second direction DR2 may form an acute angle or an obtuse angle with the first direction DR1. A third direction DR3 intersecting a plane formed by the first direction DR1 and the second direction DR2 may be defined. For example, the third direction DR3 may be perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2.

FIG. 2 is a schematic block diagram illustrating a display device of FIG. 1.

Referring to FIGS. 1 and 2, as described above, the non-display area NDA may include the drivers. The drivers may include a driving controller 100, a gate driver 200, a gamma reference voltage generator 300, a data driver 400, and a compensator 500.

The display area DA may include multiple data lines DT1, . . . , DTm, multiple first scan lines SCL1, . . . , SCLn, multiple second scan lines SSL1, . . . , SSLn, multiple sensing lines SL1, . . . , SLm and the pixels PX. Each of the pixels PX may be electrically connected to a corresponding data line among the data lines DT1, . . . , DTm, a corresponding first scan line among the first scan lines SCL1, . . . , SCLn, a corresponding second scan line among the second scan lines SSL1, . . . , SSLn, and a corresponding sensing line among the sensing lines SL1, . . . , SLm. For convenience of description, in FIG. 2, a pixel PX connected to an i-th data line DTi, an i-th first scan line SCLi, an i-th second scan line SSLi, and an i-th sensing line SLi is illustrated.

The first scan lines SCL1, . . . , SCLn may extend in the first direction DR1 and may be repeatedly disposed in the second direction DR2. The second scan lines SSL1, . . . , SSLn may extend in the first direction DR1 and may be repeatedly arranged in the second direction DR2. The first scan lines SCL1, . . . , SCLn and the second scan lines SSL1, . . . , SSLn may be disposed repeatedly alternatively. The data lines DT1, . . . , DTm may extend in the second direction DR2 and may be repeatedly disposed in the first direction DR1. The sensing lines SL1, . . . , SLm may extend in the second direction DR2 and may be repeatedly disposed in the first direction DR1.

The driving controller 100 may receive input image data IMG and input control signal CONT from an external device. In an embodiment, the input image data IMG may include red image data, green image data, and blue image data. In another embodiment, the input image data IMG may include white image data. In another embodiment, the input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 100 may generate a first control signal CONT1, a second control signal CONT2, a third control signal CONT3, a fourth control signal CONT4, and a data signal DATA based on the input image data IMG and the input control signal CONT.

The driving controller 100 may generate the first control signal CONT1 for controlling an operation of the gate driver 200 based on the input control signal CONT and output the first control signal CONT1 to the gate driver 200. The first control signal CONT1 may include a vertical start signal and a gate clock signal.

The driving controller 100 may generate a second control signal CONT2 for controlling an operation of the data driver 400 based on the input control signal CONT and output the second control signal CONT2 to the data driver 400. The second control signal CONT2 may include a horizontal start signal and a load signal.

The driving controller 100 may generate the third control signal CONT3 for controlling an operation of the gamma reference voltage generator 300 based on the input control signal CONT and output the third control signal CONT3 to the gamma reference voltage generator 300.

The driving controller 100 may generate the fourth control signal CONT4 for controlling an operation of the compensator 500 based on the input control signal CONT and output the fourth control signal COTN4 to the compensator 500.

The driving controller 100 may generate the data signal DATA based on the input image data IMG. The driving controller 100 may output the data signal DATA to the data driver 400.

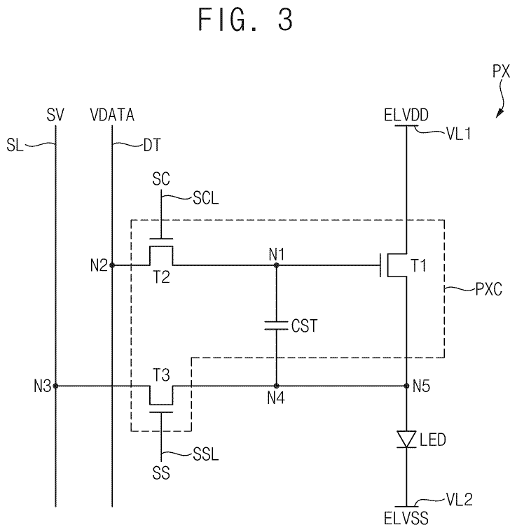

The gate driver 200 may generate scan signals for sending to the first scan lines SCL1, . . . , SCLn and the second scan lines SSL1, . . . , SSLn in response to the first control signal CONT1 input from the driving controller 100. The gate driver 200 may output the scan signals to the first scan lines SCL1, . . . , SCLn and the second scan lines SSL1, . . . , SSLn. For example, the gate driver 200 may output a first scan signal (e.g., a first scan signal SC of FIG. 3) to the first scan lines SCL1, . . . , SCLn and a second scan signal (e.g., a second scan signal SS of FIG. 3) to the second scan lines SSL1, . . . , SSLn.

The gamma reference voltage generator 300 may generate a gamma reference voltage VGREF in response to the third control signal CONT3 input from the driving controller 100. The gamma reference voltage generator 300 may provide the gamma reference voltage VGREF to the data driver 400. The gamma reference voltage VGREF may have a value corresponding to data signal DATA.

In an embodiment, the gamma reference voltage generator 300 may be spaced apart from the data driver 400 in a direction opposite to the second direction DR2. However, this disclosure is not limited thereto, and in another embodiment, the gamma reference voltage generator 300 may be disposed in the driving controller 100 or may be disposed in the data driver 400.

The data driver 400 may receive a second control signal CONT2 and the data signal DATA from the driving controller 100. The data driver 400 may receive the gamma reference voltage VGREF from the gamma reference voltage generator 300. The data driver 400 may convert the data signal DATA into an analog data voltage using the gamma reference voltage VGREF. The data driver 400 may output the data voltage to the data lines DT1, . . . , DTm. For example, the data driver 400 may output a data voltage (for example, a data voltage VDATA of FIG. 3) to the data lines DT1, . . . , DTm.

The compensator 500 may generate sensing signals for sending to the sensing lines SL1, . . . , SLm in response to the fourth control signal CONT4 input from the driving controller 100. For example, the compensator 500 may output a sensing signal (for example, a sensing signal SV of FIG. 3) to the sensing lines SL1, . . . , SLm.

In an embodiment, the gate driver 200 may be spaced apart from the display area DA in a direction opposite to the first direction DR1, and the compensator 500 may be spaced apart from the display area DA in the second direction DR2. However, this disclosure is not limited thereto. For example, both the gate driver 200 and the compensator 500 may be spaced apart from the display area DA in the direction opposite to the first direction DR1.

FIG. 3 is a schematic diagram of an equivalent circuit illustrating a circuit structure of a pixel included in the display device of FIG. 1.

Referring to FIG. 3, the pixel PX may include a light emitting element LED and a pixel driving circuit part PXC electrically connected to the light emitting element LED. In an embodiment, the pixel driving circuit part PXC may include a first transistor T1, a second transistor T2, a third transistor T3, and a capacitor CST.

In FIG. 3, each of the first transistor T1, the second transistor T2, and the third transistor T3 is illustrated as an n-type transistor. However, this disclosure is not limited thereto. For example, some of the first transistor T1, the second transistor T2, and the third transistor T3 may be n-type transistors, and others may be p-type transistors.

An active pattern of the n-type transistor may include an oxide semiconductor material, and an active pattern of the p-type transistor may include a silicon semiconductor material. However, this disclosure is not limited thereto, and each of the active pattern of the n-type transistor and the active pattern of the p-type transistor may include a silicon semiconductor material.

The pixel driving circuit part PXC may be electrically connected to a sensing line SL, a data line DT, a first scan line SCL, a second scan line SSL, a first voltage line VL1, and a second voltage line VL2.

The data line DT may apply a data voltage VDATA. The first voltage line VL1 may apply a first power voltage ELVDD having a relatively high voltage level. The second voltage line VL2 may apply a second power voltage ELVSS having a relatively low voltage level. The sensing line SL may apply a sensing signal SV. The first scan line SCL may apply a first scan signal SC. The second scan line SSL may apply a second scan signal SS.

The first transistor T1 may include a gate electrode, a first electrode, and a second electrode. The gate electrode of the first transistor T1 may be connected to a first node N1. The first electrode of the first transistor T1 may be connected to a fifth node N5. The second electrode of the first transistor T1 may be connected to the first voltage line VL1.

The second transistor T2 may include a gate electrode, a first electrode, and a second electrode. The gate electrode of the second transistor T2 may be connected to the first scan line SCL. The first electrode of the second transistor T2 may be connected to a second node N2. The first electrode of the second transistor T2 may be connected to the data line DT through the second node N2. The second electrode of the second transistor T2 may be connected to the first node N1.

The second transistor T2 may be turned on or off in response to the first scan signal SC. For example, in case that the second transistor T2 is an n-type transistor, the second transistor T2 may be turned off in case that the first scan signal SC has a negative voltage level, and may be turned on in case that the first scan signal SC has a positive voltage level. In case that the second transistor T2 is a p-type transistor, the second transistor T2 may be turned off in case that the first scan signal SC has a positive voltage level, and may be turned on in case that the first scan signal SC has a negative voltage level. The second electrode of the second transistor T2 may provide the data voltage VDATA to the first node N1 during a period in which the second transistor T2 is turned on. Accordingly, the second transistor T2 may drive the first transistor T1.

The third transistor T3 may include a gate electrode, a first electrode, and a second electrode. The gate electrode of the third transistor T3 may be connected to the second scan line SSL. The first electrode of the third transistor T3 may be connected to a fourth node N4. The second electrode of the third transistor T3 may be connected to a third node N3. The second electrode of the third transistor T3 may be connected to the sensing line SL through the third node N3.

The third transistor T3 may be turned on or off in response to the second scan signal SS. For example, in case that the third transistor T3 is an n-type transistor, the third transistor T3 may be turned off in case that the second scan signal SS has a negative voltage level, and may be turned on in case that the second scan signal SS has a positive voltage level. In case that the third transistor T3 is a p-type transistor, the third transistor T3 may be turned off in case that the second scan signal SS has a positive voltage level, and may be turned on in case that the second scan signal SS has a negative voltage level. The third transistor T3 may provide the sensing signal SV to the fourth node N4 during a period in which the third transistor T3 is turned on.

The capacitor CST may include a first electrode and a second electrode. The first electrode of the capacitor CST may be connected to the first node N1. The second electrode of the capacitor CST may be connected to the fourth node N4. The capacitor CST may be charged and discharged according to the data voltage VDATA transferred to the first node N1.

The light emitting element LED may include a first electrode and a second electrode. The first electrode of the light emitting element LED may be connected to the fifth node N5. The second electrode of the light emitting element LED may be connected to the second voltage line VL2. For example, the first electrode of the light emitting element LED may be an anode electrode, and the second electrode of the light emitting element LED may be a cathode electrode.

FIG. 3 may illustrate an embodiment in which the pixel driving circuit part PXC includes the first transistor T1, the second transistor T2, the third transistor T3, and the capacitor CST. However, this disclosure is not limited thereto. For example, the pixel driving circuit part PXC may include four or more transistors and two or more capacitors.

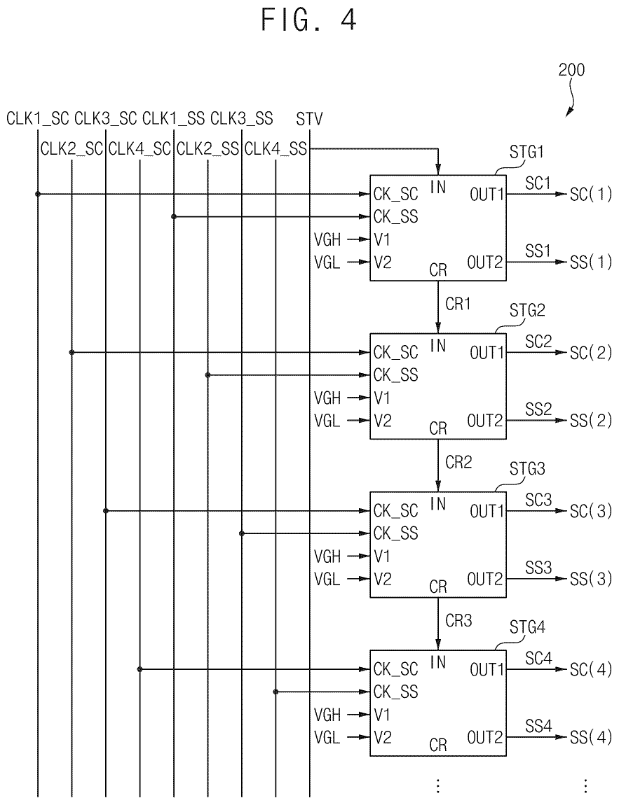

FIG. 4 is a schematic diagram illustrating a gate driver included in the display device of FIG. 1.

Referring to FIG. 4, the gate driver 200 may include multiple stages. For example, the gate driver 200 may include a first stage STG1, a second stage STG2, a third stage STG3, and a fourth stage STG4.

Each of the stages may be connected to a corresponding first scan line among the first scan lines. Each of the stages may be connected to a corresponding second scan line among the second scan lines. For example, the first stage STG1 may be connected to a first scan line SC1 and a second scan line SS1. The second stage STG2 may be connected to a first scan line SC2 and a second scan line SS2. The third stage STG3 may be connected to a first scan line SC3 and a second scan line SS3. The fourth stage STG4 may be connected to a first scan line SC4 and a second scan line SS4.

Each of the stages may be connected to a corresponding first clock line among the first clock lines. Each of the stages may be connected to a corresponding second clock line among the second clock lines. For example, the first stage STG1 may be connected to a first clock line CLK1_SC and a second clock line CLK1_SS. The second stage STG2 may be connected to a first clock line CLK2_SC and a second clock line CLK2_SS. The third stage STG3 may be connected to a first clock line CLK3_SC and a second clock line CLK3_SS. The fourth stage STG4 may be connected to a first clock line CLK4_SC and a second clock line CLK4_SS.

In an embodiment, the first clock lines may include four first clock lines CLK1_SC, CLK2_SC, CLK3_SC, and CLK4_SC. However, this disclosure is not limited thereto, and the number of the first clock lines may be changed according to embodiments. For example, the first clock lines may include six first clock lines.

In an embodiment, the second clock lines may include four second clock lines CLK1_SS, CLK2_SS, CLK3_SS, and CLK4_SS. However, this disclosure is not limited thereto, and the number of the second clock lines may be changed according to embodiments. For example, the second clock lines may include six second clock lines.

Each of the stages may include an input terminal IN, a first clock terminal CK_SC, a second clock terminal CK_SS, a first power terminal V1, a second power terminal V2, a carry terminal CR, a first output terminal OUT1, and a second output terminal OUT2.

The carry terminal CR may be electrically connected to the input terminal IN of the stage after the corresponding stage. The carry terminal CR may output a carry signal of the corresponding stage. For example, a carry terminal CR of the first stage STG1 may output a first carry signal CR1, a carry terminal CR of the second stage STG2 may output a second carry signal CR2, and a carry terminal CR of the third stage STG3 may output a third carry signal CR3.

A scan start signal STV or a previous carry signal may be applied to the input terminal IN. In an embodiment, the scan start signal STV may be applied to an input terminal IN of the first stage STG1, and a carry signal of the previous stage may be applied to the input terminal IN of the stages other than the first stage STG1. For example, the first carry signal CR1 may be applied to the input terminal IN of the second stage STG2, the second carry signal CR2 may be applied to the input terminal IN of the third stage STG3, and the third carry signal CR3 may be applied to the input terminal IN of the fourth stage STG4. However, this disclosure is not limited thereto. For example, the scan start signal STV may be applied to the input terminal IN of each of the first stage STG1 and the second stage STG2.

The first clock terminal CK_SC may be connected to the first clock lines. For example, the first clock terminal CK_SC may be connected to one of the four first clock lines CLK1_SC, CLK2_SC, CLK3_SC, and CLK4_SC. In an embodiment, a first clock terminal CK_SC of the first stage STG1 may be connected to the first clock line CLK1_SC. A first clock terminal CK_SC of the second stage STG2 may be connected to the first clock line CLK2_SC. A first clock terminal CK_SC of the third stage STG3 may be connected to the first clock line CLK3_SC. A first clock terminal CK_SC of the fourth stage STG4 may be connected to the first clock line CLK4_SC. First clock signals may be applied from the first clock lines to the first clock terminal CK_SC.

The second clock terminal CK_SS may be connected to the second clock lines. For example, the second clock terminal CK_SS may be connected to one of the four second clock lines CLK1_SS, CLK2_SS, CLK3_SS, and CLK4_SS. In an embodiment, a second clock terminal CK_SS of the first stage STG1 may be connected to the second clock line CLK1_SS. A second clock terminal CK_SS of the second stage STG2 may be connected to the second clock line CLK2_SS. A second clock terminal CK_SS of the third stage STG3 may be connected to the second clock line CLK3_SS. A second clock terminal CK_SS of the fourth stage STG4 may be connected to the second clock line CLK4_SS. Second clock signals may be applied from the second clock lines to the second clock terminal CK_SS.

A first power voltage VGH may be applied to the first power terminal V1 of the stages. A second power voltage VGL may be applied to the second power terminal V2 of the stages.

The first output terminal OUT1 may output a first scan signal. For example, a first output terminal OUT1 of the first stage STG1 may output a first scan signal SC(1). A first output terminal OUT1 of the second stage STG2 may output a first scan signal SC(2). A first output terminal OUT1 of the third stage STG3 may output a first scan signal SC(3). A first output terminal OUT1 of the fourth stage STG4 may output a first scan signal SC(4).

The second output terminal OUT2 may output a second scan signal. For example, a second output terminal OUT2 of the first stage STG1 may output a second scan signal SS(1). A second output terminal OUT2 of the second stage STG2 may output a second scan signal SS(2). A second output terminal OUT2 of the third stage STG3 may output a second scan signal SS(3). A second output terminal OUT2 of the fourth stage STG4 may output a second scan signal SS(4).

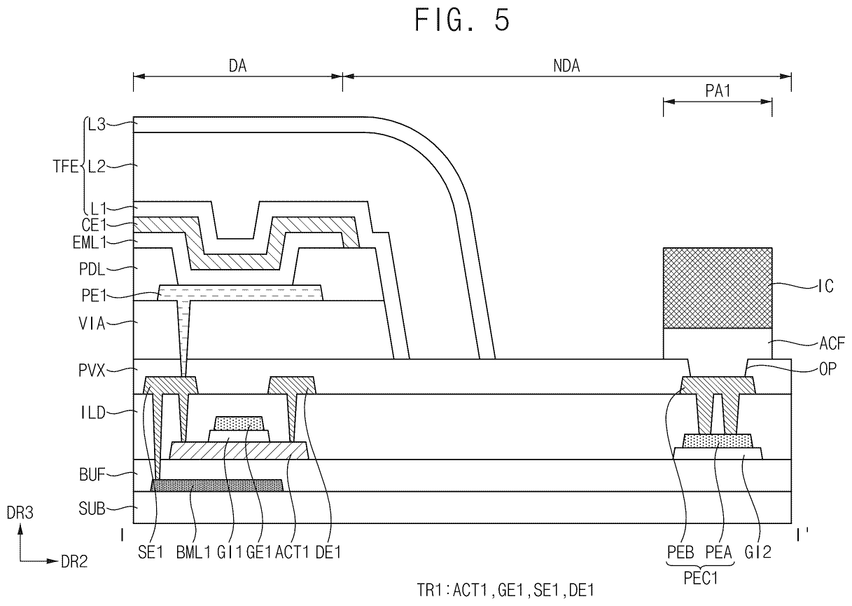

FIG. 5 is a schematic cross-sectional view of the display device of FIG. 1 taken along line I-I′.

Referring to FIGS. 1 and 5, the display device DD may include a substrate SUB, a buffer layer BUF, a first lower metal pattern BLM1, a first transistor TR1, a first gate insulating layer GI1, a second gate insulating layer GI2, an interlayer insulating layer ILD, a passivation layer PVX, a second pad electrode PEC1, a via insulating layer VIA, a first pixel electrode PE1, a first light emitting layer EML1, a first common electrode CE1, a pixel defining layer PDL, an encapsulation layer TFE, a connection member ACF, and a driving chip IC.

The substrate SUB may include a transparent material or an opaque material. The substrate SUB may be a transparent resin substrate. Example of the transparent resin substrate may include a polyimide substrate. The polyimide substrate may include a first organic layer, a first barrier layer, a second organic layer, and the like.

In another embodiment, the substrate SUB may include a quartz (e.g. a synthetic quartz substrate, a fluorine-doped quartz substrate), a calcium fluoride, a soda lime glass, a non-alkali glass, or the like. These materials may be used alone or in combination with each other.

The first lower metal pattern BML1 may be disposed on the substrate SUB. The first lower metal pattern BML1 may be disposed in the display area DA. For example, the first lower metal pattern BML1 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The buffer layer BUF may be disposed on the substrate SUB. The buffer layer BUF may cover the first lower metal pattern BML1. The buffer layer BUF may prevent metal atoms or impurities from being diffused from the substrate SUB into a first active pattern ACT1.

For example, the buffer layer BUF may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first transistor TR1 may include a first active pattern ACT1, a first gate electrode GE1, a first contact electrode SE1, and a second contact electrode DE1. The first transistor TR1 may be disposed in the display area DA. For example, the first transistor TR1 may be disposed in the display area DA on the substrate SUB. In an embodiment, the first transistor TR1 may be disposed in a portion of the display area DA adjacent to the first pad area PA1.

The first active pattern ACT1 may be disposed on the buffer layer BUF. The first active pattern ACT1 may at least partially overlap the first lower metal pattern BML1 in a plan view. For example, the first active pattern ACT1 may include an oxide semiconductor material, a silicon semiconductor material, and/or an organic semiconductor material. The first active pattern ACT1 may include a first contact area, a second contact area, and a channel area between the first contact area and the second contact area. The first contact area and the second contact area may have higher conductivity than the channel area.

In an embodiment, the first active pattern ACT1 may include an oxide semiconductor material. However, this disclosure is not limited thereto, and in another embodiment, the first active pattern ACT1 may include a silicon semiconductor material. Examples of the oxide semiconductor material that can be used as the first active pattern ACT1 may include indium gallium zinc oxide (“IGZO”), zinc tin oxide (“ZTO”), indium tin zinc oxide (“ITZO”), or the like. These materials may be used alone or in combination with each other.

The first gate insulating layer GI1 may be disposed on the first active pattern ACT1. The first gate insulating layer GI1 may cover at least a portion of the first active pattern ACT1. For example, the first gate insulating layer GI1 may cover an upper surface of the first active pattern ACT1.

For example, the first gate insulating layer GI1 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first gate electrode GE1 may be disposed on the first gate insulating layer GI1. The first gate electrode GE1 may overlap the channel area of the first active pattern ACT1 in a plan view.

For example, the first gate electrode GE1 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be disposed on the first gate electrode GE1. The interlayer insulating layer ILD may sufficiently cover the first gate electrode GE1. For example, the interlayer insulating layer ILD may cover the first gate electrode GE1 and may be disposed along a profile of the first gate electrode GE1.

For example, the interlayer insulating layer ILD may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first contact electrode SE1 and the second contact electrode DE1 may be disposed on the interlayer insulating layer ILD. The first contact electrode SE1 may be in contact with the first contact area of the first active pattern ACT1. For example, the first contact electrode SE1 may be in contact with the first contact area of the first active pattern ACT1 through a contact hole defining through the interlayer insulating layer ILD. The second contact electrode DE1 may be in contact with the second contact area of the first active pattern ACT1. For example, the second contact electrode DE1 may be in contact with the second contact area of the first active pattern ACT1 through a contact hole defining through the interlayer insulating layer ILD.

For example, each of the first contact electrode SE1 and the second contact electrode DE1 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first contact electrode SE1 may be in contact with the first lower metal pattern BML1. For example, the first contact electrode SE1 may be in contact with the first lower metal pattern BML1 through a contact hole defining through the interlayer insulating layer ILD and the buffer layer BUF. However, this disclosure is not limited thereto. For example, in case that the first gate electrode GE1 is in contact with the first lower metal pattern BML1, the first contact electrode SE1 may not be in contact with the first lower metal pattern BML1.

The second gate insulating layer GI2 may be disposed on the buffer layer BUF. The second gate insulating layer GI2 may be disposed in the non-display area NDA. For example, the second gate insulating layer GI2 may be disposed in the first pad area PA1.

For example, the second gate insulating layer GI2 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

A first auxiliary pad electrode PEA may be disposed on the second gate insulating layer GI2. For example, the first auxiliary pad electrode PEA may be disposed in the first pad area PA1.

For example, the first auxiliary pad electrode PEA may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first auxiliary pad electrode PEA and the first gate electrode GE1 may include substantially the same material. However, this disclosure is not limited thereto, and in another embodiment, the first auxiliary pad electrode PEA and the first gate electrode GE1 may include different materials.

A second auxiliary pad electrode PEB may be disposed on the interlayer insulating layer ILD. For example, the second auxiliary pad electrode PEB may be disposed in the first pad area PA1. The second auxiliary pad electrode PEB may overlap the first auxiliary pad electrode PEA in a plan view. The second auxiliary pad electrode PEB may be in contact with the first auxiliary pad electrode PEA. For example, the second auxiliary pad electrode PEB may be in contact with the first auxiliary pad electrode PEA through a contact hole defining through the interlayer insulating layer ILD.

For example, the second auxiliary pad electrode PEB may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the second auxiliary pad electrode PEB and the first contact electrode SE1 may include substantially the same material. However, this disclosure is not limited thereto, and in another embodiment, the second auxiliary pad electrode PEB and the first contact electrode SE1 may include different materials.

Accordingly, the first pad electrode PEC1 including the first auxiliary pad electrode PEA and the second auxiliary pad electrode PEB may be formed.

The passivation layer PVX may be disposed on the interlayer insulating layer ILD. The passivation layer PVX may cover the first contact electrode SE1, the second contact electrode DE1, and the second auxiliary pad electrode PEB.

For example, the passivation layer PVX may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The via insulating layer VIA may be disposed on the passivation layer PVX. The via insulating layer VIA may include an organic material. For example, the via insulating layer VIA may include an organic material such as a phenolic resin, a polyacrylate resin, a polyimide resin, a polyamide resin, a siloxane resin, an epoxy resin, or the like. These materials may be used alone or in combination with each other.

The first pixel electrode PE1 may be disposed on the via insulating layer VIA. The first pixel electrode PE1 may be disposed in the display area DA. The first pixel electrode PE1 may contact the first contact electrode SE1. For example, the first pixel electrode PE1 may contact the first contact electrode SE1 through a contact hole defining through the via insulating layer VIA and the passivation layer PVX.

For example, the first pixel electrode PE1 may include a metal, an alloy, a metal nitride, a conductive metal oxide, a transparent conductive material, or the like. These materials may be used alone or in combination with each other. In an embodiment, the first pixel electrode PE1 may have a stacked structure including ITO/Ag/ITO. The first pixel electrode PE1 may operate as an anode.

The pixel defining layer PDL may be disposed on the via insulating layer VIA. The pixel defining layer PDL may cover a side portion of the first pixel electrode PE1. For example, a pixel opening exposing at least a portion of an upper surface of the first pixel electrode PE1 may be defined in the pixel defining layer PDL.

For example, the pixel defining layer PDL may include an inorganic material or an organic material. In an embodiment, the pixel defining layer PDL may include an organic material such as an epoxy resin, a siloxane resin, or the like. These materials may be used alone or in combination with each other. In another embodiment, the pixel defining layer PDL may further include a light blocking material including a black pigment, a black dye, or the like.

The first light emitting layer EML1 may be disposed on the first pixel electrode PE1 and the pixel defining layer PDL. A portion of the first light emitting layer EML1 may be disposed in the pixel opening of the pixel defining layer PDL. In an embodiment, the first light emitting layer EML1 may include a first functional layer including an organic material, a light emitting layer including a light emitting material, and a second functional layer including an organic material. For example, the first functional layer may include a hole injection layer, a hole transport layer, and the like, and the second functional layer may include an electron transport layer, an electron injection layer, and the like.

The first common electrode CE1 may be disposed on the first light emitting layer EML1. The first common electrode CE1 may include a metal, an alloy, a metal nitride, a conductive metal oxide, a transparent conductive material, or the like. These materials may be used alone or in combination with each other. The first common electrode CE1 may operate as a cathode.

The encapsulation layer TFE may be disposed on the first common electrode CE1. The encapsulation layer TFE may include a first inorganic encapsulation layer L1, an organic encapsulation layer L2, and a second inorganic encapsulation layer L3. The first inorganic encapsulation layer L1 may cover the first common electrode CE1, the pixel defining layer PDL, and the via insulating layer VIA. For example, the first inorganic encapsulation layer L1 may include an inorganic insulating material. The organic encapsulation layer L2 may be disposed on the first inorganic encapsulation layer L1. For example, the organic encapsulation layer L2 may include an organic insulating material. The second inorganic encapsulation layer L3 may be disposed on the organic encapsulation layer L2. For example, the second inorganic encapsulation layer L3 may include an inorganic insulating material.

Although not illustrated in FIG. 5, in an embodiment, a touch sensing layer may be disposed on the encapsulation layer TFE. For example, the touch sensing layer may include multiple touch electrode arrays for sensing a user's processing in a capacitive manner, a touch pad part, and multiple touch wires electrically connecting the touch pad part to the touch electrode arrays. However, this disclosure is not limited thereto. In another embodiment, the touch sensing layer may be omitted.

In an embodiment, the passivation layer PVX may include an opening OP. The opening OP may be disposed in the first pad area PA1. An upper surface of the second auxiliary pad electrode PEB may be exposed through the opening OP.

The connection member ACF may be disposed on the passivation layer PVX. The connection member ACF may fill the opening OP. The driving chip IC and the first pad electrode PEC1 may be electrically connected to each other through the connection member ACF. For example, the driving chip IC and the second auxiliary pad electrode PEB may be electrically connected to each other through the connection member ACF.

In an embodiment, the connection member ACF may include an anisotropic conductive film. For example, the connection member ACF may include an adhesive layer and conductive particles. Each of the conductive particles may include a core including an insulating polymer material and a conductive layer surrounding the core and including a conductive metal material.

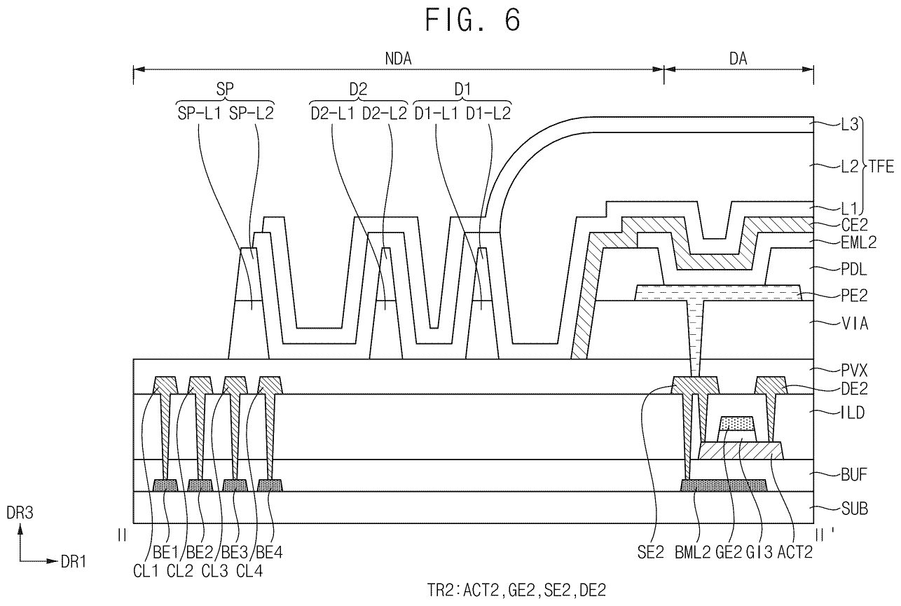

FIG. 6 is a schematic cross-sectional view of the display device of FIG. 1 taken along line II-II′.

Referring to FIGS. 1 and 6, the display device DD may further include a second lower metal pattern BML2, a second transistor TR2, a second pixel electrode PE2, a second light emitting layer EML2, a second common electrode CE2, a first dam D1, a second dam D2, a support part SP, a first conductive layer CL1, a second conductive layer CL2, a third conductive layer CL3, a fourth conductive layer CL4, a first lower auxiliary electrode BE1, a second lower auxiliary electrode BE2, a third lower auxiliary electrode BE3, a fourth lower auxiliary electrode BE4, and the third gate insulating layer GI3.

The second lower metal pattern BML2 may be disposed on the substrate SUB. The second lower metal pattern BML2 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first lower auxiliary electrode BE1, the second lower auxiliary electrode BE2, the third lower auxiliary electrode BE3 and the fourth lower auxiliary electrode BE4 may be disposed on the substrate SUB. Each of the first lower auxiliary electrode BE1, the second lower auxiliary electrode BE2, the third lower auxiliary electrode BE3 and the fourth lower auxiliary electrode BE4 may be disposed in the non-display area NDA. For example, each of the first lower auxiliary electrode BE1, the second lower auxiliary electrode BE2, the third lower auxiliary electrode BE3 and the fourth lower auxiliary electrode BE4 may be disposed in the gate driver 200.

Each of the first lower auxiliary electrode BE1, the second lower auxiliary electrode BE2, the third lower auxiliary electrode BE3, and the fourth lower auxiliary electrode BE4 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlN&”), tungsten nitride (“WNₓ”), chromium nitride (“CrNₓ”), or the like. These materials may be used alone or in combination with each other.

In an embodiment, the first lower auxiliary electrode BE1, the second lower auxiliary electrode BE2, the third lower auxiliary electrode BE3, the fourth lower auxiliary electrode BE4 and the second lower metal pattern BML2 may be disposed on a same layer and may include substantially the same material.

The buffer layer BUF may be disposed on the substrate SUB. The buffer layer BUF may cover the second lower metal pattern BML2, the first lower auxiliary electrode BE1, the second lower auxiliary electrode BE2, the third lower auxiliary electrode BE3, and the fourth lower auxiliary electrode BE4. The buffer layer BUF may prevent metal atoms or impurities from being diffused from the substrate SUB into a second active pattern ACT2.

The second transistor TR2 may include a second active pattern ACT2, a second gate electrode GE2, a third contact electrode SE2, and a fourth contact electrode DE2. The second transistor TR2 may be disposed in the display area DA. For example, the second transistor TR2 may be disposed in the display area DA on the substrate SUB. In an embodiment, the second transistor TR2 may be disposed in a portion of the display area DA adjacent to the non-display area NDA.

The second active pattern ACT2 may be disposed on the buffer layer BUF. The second active pattern ACT2 may at least partially overlap the second lower metal pattern BML2 in a plan view. For example, the second active pattern ACT2 may include an oxide semiconductor material, a silicon semiconductor material, and/or an organic semiconductor material. The second active pattern ACT2 may include a first contact area, a second contact area, and a channel area between the first contact area and the second contact area. The first contact area and the second contact area may have higher conductivity than the channel area.

In an embodiment, the second active pattern ACT2 may include an oxide semiconductor material. However, this disclosure is not limited thereto, and in another embodiment, the second active pattern ACT2 may include a silicon semiconductor material. Examples of the oxide semiconductor material that can be used as the second active pattern ACT2 may include indium gallium zinc oxide (“IGZO”), zinc tin oxide (“ZTO”), indium tin zinc oxide (“ITZO”), or the like. These materials may be used alone or in combination with each other.

The third gate insulating layer GI3 may be disposed on the second active pattern ACT2. The third gate insulating layer GI3 may cover at least a portion of the second active pattern ACT2. For example, the third gate insulating layer GI3 may cover an upper surface of the second active pattern ACT2.

For example, the third gate insulating layer GI3 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The second gate electrode GE2 may be disposed on the third gate insulating layer GI3. The second gate electrode GE2 may overlap the channel area of the second active pattern ACT2 in a plan view.

For example, the second gate electrode GE2 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be disposed on the second gate electrode GE2. The interlayer insulating layer ILD may sufficiently cover the second gate electrode GE2. For example, the interlayer insulating layer ILD may cover the second gate electrode GE2 and may be disposed along a profile of the second gate electrode GE2.

The third contact electrode SE2 and the fourth contact electrode DE2 may be disposed on the interlayer insulating layer ILD. The third contact electrode SE2 may be in contact with the first contact area of the second active pattern ACT2. For example, the third contact electrode SE2 may be in contact with the first contact area of the second active pattern ACT2 through a contact hole defining through the interlayer insulating layer ILD. The fourth contact electrode DE2 may be in contact with the second contact area of the second active pattern ACT2. For example, the fourth contact electrode DE2 may be in contact with the second contact area of the second active pattern ACT2 through a contact hole defining through the interlayer insulating layer ILD.

For example, each of the third contact electrode SE2 and the fourth contact electrode DE2 may include a conductive material such as a metal, an alloy, a conductive metal oxide, a conductive metal nitride, a transparent conductive oxide, or the like. These materials may be used alone or in combination with each other. These may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the third contact electrode SE2 may be in contact with the second lower metal pattern BML2. For example, the third contact electrode SE2 may be in contact with the second lower metal pattern BML2 through a contact hole defining through the interlayer insulating layer ILD and the buffer layer BUF. However, this disclosure is not limited thereto. For example, in case that the second gate electrode GE2 is in contact with the second lower metal pattern BML2, the third contact electrode SE2 may not be in contact with the second lower metal pattern BML2.

In an embodiment, the first conductive layer CL1, the second conductive layer CL2, the third conductive layer CL3, and the fourth conductive layer CL4 may be disposed on the interlayer insulating layer ILD. Each of the first conductive layer CL1, the second conductive layer CL2, the third conductive layer CL3, and the fourth conductive layer CL4 may be disposed in the non-display area NDA. For example, each of the first conductive layer CL1, the second conductive layer CL2, the third conductive layer CL3, and the fourth conductive layer CL4 may be disposed in the gate driver 200.

The second conductive layer CL2 may be spaced apart from the first conductive layer CL1 in a plan view. For example, in a cross-sectional view, the second conductive layer CL2 may be spaced apart from the first conductive layer CL1 in the first direction DR1. The third conductive layer CL3 may be spaced apart from the second conductive layer CL2 in a plan view. For example, in a cross-sectional view, the third conductive layer CL3 may be spaced apart from the second conductive layer CL2 in the first direction DR1. The fourth conductive layer CL4 may be spaced apart from the third conductive layer CL3 in a plan view. For example, in a cross-sectional view, the fourth conductive layer CL4 may be spaced apart from the third conductive layer CL3 in the first direction DR1.

In an embodiment, a clock signal may be applied through the first conductive layer CL1. For example, the first conductive layer CL1 may be a portion of one first clock line among the first clock lines CLK1_SC, CLK2_SC, CLK3_SC, and CLK4_SC of FIG. 4. In another embodiment, the first conductive layer CL1 may be a portion of one second clock line among the second clock lines CLK1_SS, CLK2_SS, CLK3_SS, and CLK4_SS of FIG. 4. However, this disclosure is not limited thereto, and a signal other than the clock signal may be applied to the first conductive layer CL1. For example, the first power voltage VGH or the second power voltage VGL of FIG. 4 may be applied to the first conductive layer CL1.

In an embodiment, a clock signal may be applied through the second conductive layer CL2. For example, the second conductive layer CL2 may be a portion of one first clock line among the first clock lines CLK1_SC, CLK2_SC, CLK3_SC, and CLK4_SC of FIG. 4. In another embodiment, the second conductive layer CL2 may be a portion of one second clock line among the second clock lines CLK1_SS, CLK2_SS, CLK3_SS, and CLK4_SS of FIG. 4. However, this disclosure is not limited thereto, and a signal other than the clock signal may be applied to the second conductive layer CL2. For example, the first power voltage VGH or the second power voltage VGL of FIG. 4 may be applied to the second conductive layer CL2.

In an embodiment, a clock signal may be applied through the third conductive layer CL3. For example, the third conductive layer CL3 may be a portion of one first clock line among the first clock lines CLK1_SC, CLK2_SC, CLK3_SC, and CLK4_SC of FIG. 4. In another embodiment, the third conductive layer CL3 may be a portion of one second cock line among the second clock lines CLK1_SS, CLK2_SS, CLK3_SS, and CLK4_SS of FIG. 4. However, this disclosure is not limited thereto, and a signal other than the clock signal may be applied to the third conductive layer CL3. For example, the first power voltage VGH or the second power voltage VGL of FIG. 4 may be applied to the third conductive layer CL3.

In an embodiment, a clock signal may be applied through the fourth conductive layer CL4. For example, the fourth conductive layer CL4 may be a portion of one first clock line among the first clock lines CLK1_SC, CLK2_SC, CLK3_SC, and CLK4_SC of FIG. 4. In another embodiment, the fourth conductive layer CL4 may be a portion of one second cock line among the second clock lines CLK1_SS, CLK2_SS, CLK3_SS, and CLK4_SS of FIG. 4. However, this disclosure is not limited thereto, and a signal other than the clock signal may be applied to the fourth conductive layer CL4. For example, the first power voltage VGH or the second power voltage VGL of FIG. 4 may be applied to the fourth conductive layer CL4.

The first conductive layer CL1 may be in contact with the first lower auxiliary electrode BE1. For example, the first conductive layer CL1 may be in contact with the first lower auxiliary electrode BE1 through a contact hole defining through the interlayer insulating layer ILD and the buffer layer BUF. The second conductive layer CL2 may be in contact with the second lower auxiliary electrode BE2. For example, the second conductive layer CL2 may be in contact with the second lower auxiliary electrode BE2 through a contact hole defining through the interlayer insulating layer ILD and the buffer layer BUF. The third conductive layer CL3 may be in contact with the third lower auxiliary electrode BE3. For example, the third conductive layer CL3 may be in contact with the third lower auxiliary electrode BE3 through a contact hole defining through the interlayer insulating layer ILD and the buffer layer BUF. The fourth conductive layer CL4 may be in contact with the fourth lower auxiliary electrode BE4. For example, the fourth conductive layer CL4 may be in contact with the fourth lower auxiliary electrode BE4 through a contact hole defining through the interlayer insulating layer ILD and the buffer layer BUF.

For example, each of the first conductive layer CL1, the second conductive layer CL2, the third conductive layer CL3, and the fourth conductive layer CL4 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first conductive layer CL1, the second conductive layer CL2, the third conductive layer CL3, the fourth conductive layer CL4, and the third contact electrode SE2 may be disposed on a same layer and may include substantially the same material. However, this disclosure is not limited thereto.

The passivation layer PVX may be disposed on the interlayer insulating layer ILD. The passivation layer PVX may cover the first conductive layer CL1, the second conductive layer CL2, the third conductive layer CL3, the fourth conductive layer CL4, the third contact electrode SE2, and the fourth contact electrode DE2. For example, the passivation layer PVX may be referred to as a first insulating layer.

The via insulating layer VIA may be disposed on the passivation layer PVX.

The second pixel electrode PE2 may be disposed on the via insulating layer VIA. The second pixel electrode PE2 may be disposed in the display area DA. The second pixel electrode PE2 may be in contact with the third contact electrode SE2. For example, the second pixel electrode PE2 may be in contact with the third contact electrode SE2 through a contact hole defining through the via insulating layer VIA and the passivation layer PVX.

For example, the second pixel electrode PE2 may include a metal, an alloy, a metal nitride, a conductive metal oxide, a transparent conductive material, or the like. These materials may be used alone or in combination with each other. In an embodiment, the second pixel electrode PE2 may have a stacked structure including ITO/Ag/ITO. The second pixel electrode PE2 may operate as an anode. For example, the second pixel electrode PE2 may be referred to as a first electrode.

The pixel defining layer PDL may be disposed on the via insulating layer VIA. The pixel defining layer PDL may cover a side portion of the second pixel electrode PE2. For example, a pixel opening exposing at least a portion of an upper surface of the second pixel electrode PE2 may be defined in the pixel defining layer PDL.

The second light emitting layer EML2 may be disposed on the second pixel electrode PE2 and the pixel defining layer PDL. A portion of the second light emitting layer EML2 may be disposed in the pixel opening of the pixel defining layer PDL. In an embodiment, the second light emitting layer EML2 may include a first functional layer including an organic material, a light emitting layer including a light emitting material, and a second functional layer including an organic material disposed on the light emitting layer. For example, the first functional layer may include a hole injection layer, a hole transport layer, and the like and the second functional layer may include an electron transport layer, an electron injection layer, and the like.

In an embodiment, the second light emitting layer EML2 may be connected to the first light emitting layer (e.g., the first light emitting layer EML1 of FIG. 5). For example, the first light emitting layer and the second light emitting layer EML2 may constitute a single light emitting layer. However, this disclosure is not limited thereto, and the second light emitting layer EML2 may be separated from the first light emitting layer.

The second common electrode CE2 may be disposed on the second light emitting layer EML2. The second common electrode CE2 may include a metal, an alloy, a metal nitride, a conductive metal oxide, a transparent conductive material, or the like. These materials may be used alone or in combination with each other. The second common electrode CE2 may operate as a cathode. For example, the second common electrode CE2 may be referred to as a second electrode.

In an embodiment, the second common electrode CE2 may be connected to the first common electrode (e.g., the first common electrode CE1 of FIG. 5). For example, the first common electrode and the second common electrode CE2 may constitute one common electrode. However, this disclosure is not limited thereto, and the second common electrode CE2 may be separated from the first common electrode.

The encapsulation layer TFE may be disposed on the second common electrode CE2. As mentioned above, the encapsulation layer TFE may include the first inorganic encapsulation layer L1, the organic encapsulation layer L2, and the second inorganic encapsulation layer L3.

The encapsulation layer TFE may be disposed over the entire display area DA and the non-display area NDA. For example, the first inorganic encapsulation layer L1 and the second inorganic encapsulation layer L3 may cover the display area DA and may extend to an outside of the second dam D2. In an embodiment, the first inorganic encapsulation layer L1 and the second inorganic encapsulation layer L3 may extend to an upper surface of the support part SP.

The first dam D1 and the second dam D2 may be disposed in the non-display area NDA. For example, the first dam D1 and the second dam D2 may be disposed in the non-display area NDA on the passivation layer PVX. The first dam D1 and the second dam D2 may be spaced apart from each other in a plan view. The first dam D1 may be spaced apart from the via insulating layer VIA in a direction opposite to the first direction DR1 in a cross-sectional view. The second dam D2 may be disposed outside the first dam D1 and may be spaced apart from the first dam D1 in the direction opposite to the first direction DR1 in a cross-sectional view.

When the encapsulation layer TFE is formed, the first dam D1 and the second dam D2 may prevent the encapsulation layer TFE from overflowing in an edge direction (e.g., the direction opposite to the first direction DR1 of FIG. 6) of the substrate SUB. For example, the first dam D1 and the second dam D2 may prevent the organic encapsulation layer L2 including the organic insulating material from overflowing in the edge direction of the substrate SUB.

The first dam D1 may include a first layer D1-L1 and a second layer D1-L2. The first layer D1-L1 and the via insulating layer VIA may include substantially the same material. The second layer D1-L2 may be disposed on the first layer D1-L1. The second layer D1-L2 and the pixel defining layer PDL may include substantially the same material.

The second dam D2 may include a first layer D2-L1 and a second layer D2-L2. The first layer D2-L1 and the via insulating layer VIA may include substantially the same material. The second layer D2-L2 may be disposed on the first layer D2-L1. The second layer D2-L2 and the pixel defining layer PDL may include substantially the same material.

The support part SP may be disposed in the non-display area NDA. For example, the support part SP may be disposed in the non-display area NDA on the passivation layer PVX. The support part SP may be disposed outside the second dam D2 and may be spaced apart from the second dam D2 in the direction opposite to the first direction DR1 in a cross-sectional view.

When the encapsulation layer TFE is formed, the support part SP may prevent the encapsulation layer TFE from overflowing in the direction of the edge of the substrate SUB. For example, the support part SP may prevent the organic encapsulation layer L2 including the organic insulating material from overflowing in the direction of the edge of the substrate SUB. The support part SP may serve as a support that supports a deposition mask used when depositing the second light emitting layer EML2.

In an embodiment, the support part SP may overlap some of multiple conductive layers disposed on the interlayer insulating layer ILD in a plan view. In an embodiment, the support part SP may overlap the third conductive layer CL3 and the fourth conductive layer CL4 in a plan view. However, this disclosure is not limited thereto, and in another embodiment, the support part SP may overlap the fourth conductive layer CL4 in a plan view, and may not overlap the third conductive layer CL3 in a plan view. In another embodiment, the support part SP may overlap the second conductive layer CL2, the third conductive layer CL3, and the fourth conductive layer CL4 in a plan view. In another embodiment, the support part SP may overlap the first conductive layer CL1, the second conductive layer CL2, the third conductive layer CL3, and the fourth conductive layer CL4 in a plan view.

The support part SP may include a first layer SP-L1 and a second layer SP-L2. The first layer SP-L1 and the via insulating layer VIA may include substantially the same material. The second layer SP-L2 may be disposed on the first layer SP-L1. The second layer SP-L2 and the pixel defining layer PDL may include substantially the same material.

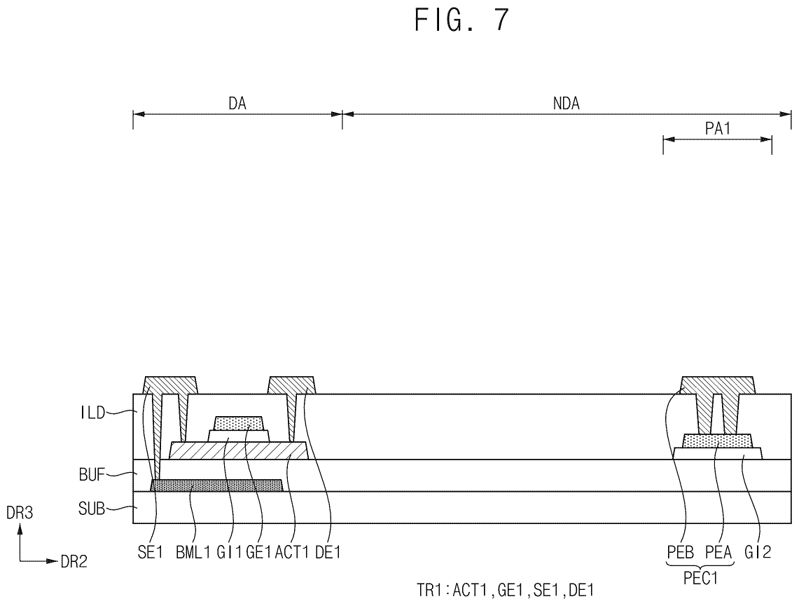

FIGS. 7, 8, 9, 10, 11, 12, 13, 14, 15, 16, 17, 18, 19, 20, 21, 22, 23, and 24 are schematic cross-sectional views illustrating a method of manufacturing the display device of FIG. 1.

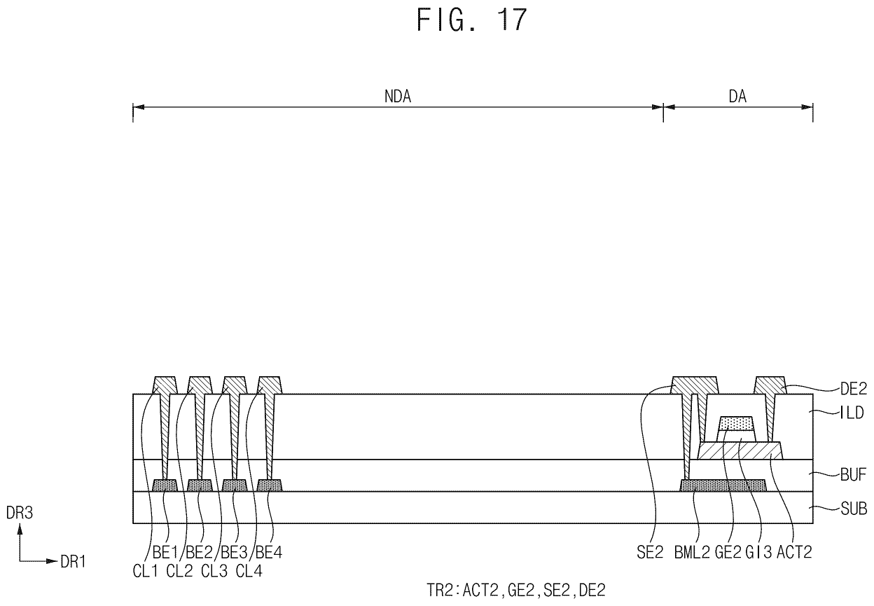

For example, FIGS. 7, 8, 9, 10, 11, 12, 13, 14, 15, and 16 are schematic cross-sectional views illustrating a method of manufacturing a display device based on a cross-sectional view of FIG. 5. FIGS. 17, 18, 19, 20, 21, 22, 23, and 24 are schematic cross-sectional views illustrating a method of manufacturing a display device based on a cross-sectional view of FIG. 6.

Referring to FIG. 7, the first lower metal pattern BML1 may be formed on the substrate SUB. The first lower metal pattern BML1 may be formed in the display area DA. For example, the first lower metal pattern BML1 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The buffer layer BUF may be formed on the substrate SUB. The buffer layer BUF may be formed to cover the first lower metal pattern BML1. For example, the buffer layer BUF may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first transistor TR1 may be formed on the substrate SUB. For example, the first active pattern ACT1 may be formed on the buffer layer BUF, the first gate electrode GE1 may be formed on the first gate insulating layer GI1, and the first contact electrode SE1 and the second contact electrode DE1 may be formed on the interlayer insulating layer ILD.

The first active pattern ACT1 may be formed to at least partially overlap the first lower metal pattern BML1 in a plan view. For example, the first active pattern ACT1 may include an oxide semiconductor material, a silicon semiconductor material, and/or an organic semiconductor material. The first active pattern ACT1 may include the first contact area, the second contact area, and the channel area between the first contact area and the second contact area. The first contact area and the second contact area may have higher conductivity than the channel area.

In an embodiment, the first active pattern ACT1 may include an oxide semiconductor material. However, this disclosure is not limited thereto, and in another embodiment, the first active pattern ACT1 may include a silicon semiconductor material. Examples of the oxide semiconductor material that can be used as the first active pattern ACT1 may include indium gallium zinc oxide (“IGZO”), zinc tin oxide (“ZTO”), indium tin zinc oxide (“ITZO”), or the like. These materials may be used alone or in combination with each other.

The second gate insulating layer GI2 may be formed on the buffer layer BUF. The second gate insulating layer GI2 may be formed in the non-display area NDA. For example, the second gate insulating layer GI2 may be formed in the first pad area PA1.

For example, the second gate insulating layer GI2 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other. The second gate insulating layer GI2 and the first gate insulating layer GI1 may include substantially the same material and may be formed through a same process.

The first gate insulating layer GI1 may be formed on the first active pattern ACT1. The first gate insulating layer GI1 may be formed to cover at least a portion of the first active pattern ACT1. For example, the first gate insulating layer GI1 may be formed to cover the upper surface of the first active pattern ACT1.

For example, the first gate insulating layer GI1 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

As described above, the first gate electrode GE1 may be formed on the first gate insulating layer GI1. The first gate electrode GE1 may overlap the channel area of the first active pattern ACT1 in a plan view.

For example, the first gate electrode GE1 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The first auxiliary pad electrode PEA may be formed on the second gate insulating layer GI2. For example, the first auxiliary pad electrode PEA may be formed in the first pad area PA1. For example, the first auxiliary pad electrode PEA may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first auxiliary pad electrode PEA and the first gate electrode GE1 may include substantially the same material and may be formed through a same process.

The interlayer insulating layer ILD may be formed on the first gate electrode GE1 and the first auxiliary pad electrode PEA. The interlayer insulating layer ILD may be formed to sufficiently cover the first gate electrode GE1 and the first auxiliary pad electrode PEA.

For example, the interlayer insulating layer ILD may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The first contact electrode SE1, the second contact electrode DE1, and the second auxiliary pad electrode PEB may be formed on the interlayer insulating layer ILD. The first contact electrode SE1 and the second contact electrode DE1 may be formed in the display area DA, and the second auxiliary pad electrode PEB may be formed in the first pad area PA1.

A contact hole for connecting the first contact electrode SE1 and the first contact area of the first active pattern ACT1 may be formed in the interlayer insulating layer ILD. A contact hole for connecting the second contact electrode DE1 and the second contact area of the first active pattern ACT1 may be formed in the interlayer insulating layer ILD. Contact holes for connecting the second auxiliary pad electrode PEB and the first auxiliary pad electrode PEA may be formed in the interlayer insulating layer ILD.

For example, each of the first contact electrode SE1, the second contact electrode DE1, and the second auxiliary pad electrode PEB may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first contact electrode SE1, the second contact electrode DE1, and the second auxiliary pad electrode PEB may include substantially the same material, and may be formed through a same process.

In an embodiment, a contact hole for connecting the first contact electrode SE1 and the first lower metal pattern BML1 may be formed in the interlayer insulating layer ILD and the buffer layer BUF.

The first auxiliary pad electrode PEA and the second auxiliary pad electrode PEB may constitute the first pad electrode PEC1.

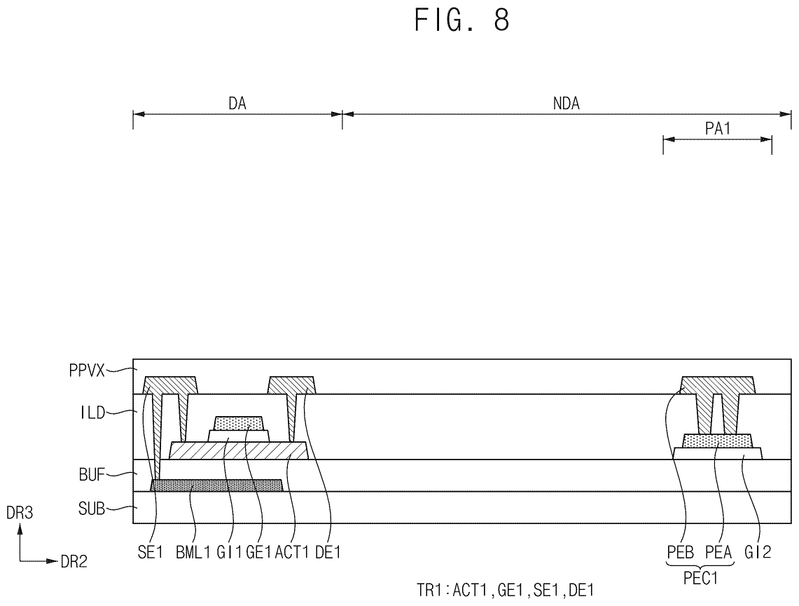

Referring to FIG. 8, a preliminary passivation layer PPVX may be formed on the interlayer insulating layer ILD. The preliminary passivation layer PPVX may be formed to cover the first contact electrode SE1, the second contact electrode DE1, and the second auxiliary pad electrode PEB. For example, the preliminary passivation layer PPVX may be referred to as a first preliminary insulating layer.

For example, the preliminary passivation layer PPVX may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

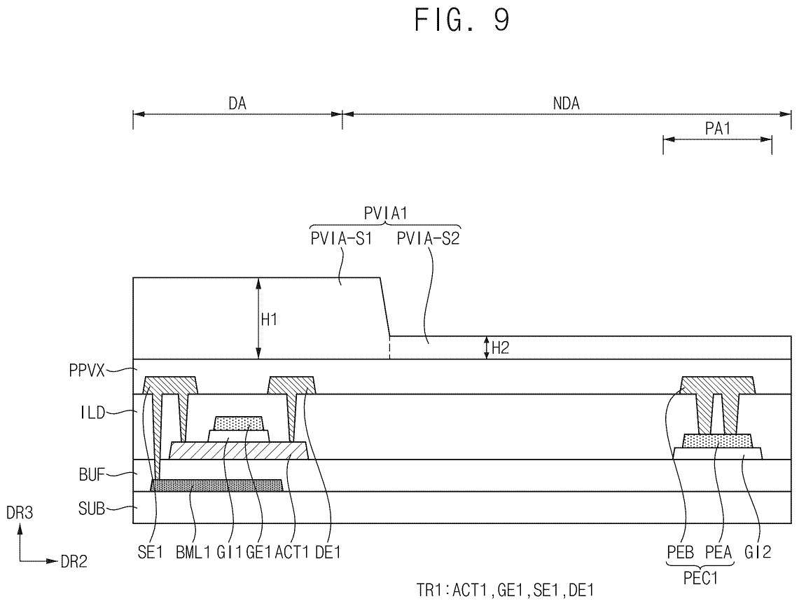

Referring to FIG. 9, a first preliminary via insulating layer PVIA1 may be formed on the preliminary passivation layer PPVX. The first preliminary via insulating layer PVIA1 may include a first portion PVIA-S1 and a second portion PVIA-S2. The first portion PVIA-S1 may be a portion at least partially overlapping the first transistor TR1 in a plan view. The second portion PVIA-S2 may be a portion at least partially overlapping the first pad electrode PEC1 in a plan view. The second portion PVIA-S2 may be in contact with the first portion PVIA-S1 in the second direction DR2.

In an embodiment, the first portion PVIA-S1 and the second portion PVIA-S2 may have different thicknesses in the third direction DR3. For example, a thickness H1 of the first portion PVIA-S1 may be greater than a thickness H2 of the second portion PVIA-S2. For example, the thickness H1 of the first portion PVIA-S1 in the third direction DR3 may be greater than the thickness H2 of the second portion PVIA-S2 in the third direction DR3.

For example, the first preliminary via insulating layer PVIA1 including the first portion PVIA-S1 and the second portion PVIA-S2 may be formed through a halftone mask including a light transmitting area and a semi-light transmitting area. For example, the semi-transmitting area may be an area through which light is transmitted through the halftone mask, the semi-transmitting area may be an area through which light in an amount less than light passing through the transmitting area is transmitted through the halftone mask. For example, the first preliminary via insulating layer PVIA1 may be referred to as a second preliminary insulating layer.

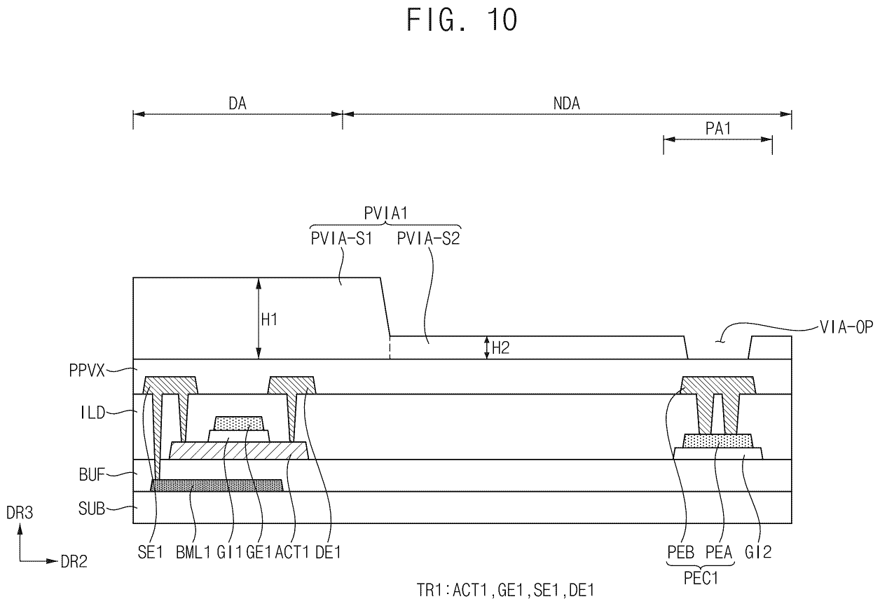

Referring to FIG. 10, a first opening VIA-OP may be formed in the first preliminary via insulating layer PVIA1. For example, the first opening VIA-OP may be formed in the second portion PVIA-S2 of the first preliminary via insulating layer PVIA1. For example, at least a portion of the first preliminary via insulating layer PVIA1 may be removed in the first pad area PA1 to form the first opening VIA-OP.

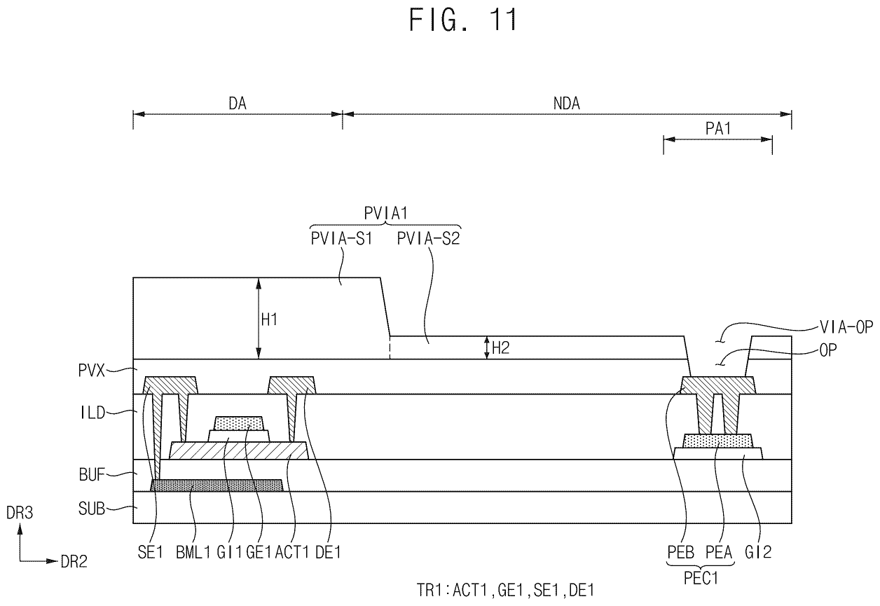

Referring to FIG. 11, a second opening OP may be formed in the preliminary passivation layer (e.g., the preliminary passivation layer PPVX of FIG. 10). Accordingly, the passivation layer PVX may be formed. For example, at least a portion of the preliminary passivation layer PPVX may be removed in the first pad area PA1 to form the second opening OP. The second opening OP may at least partially overlap the first opening VIA-OP in a plan view. For example, the second opening OP and the first opening VIA-OP may be connected to form one opening. An upper surface of the second auxiliary pad electrode PEB may be exposed through the second opening OP. For example, the upper surface of the second auxiliary pad electrode PEB may be exposed through the second opening OP and the first opening VIA-OP. The second opening OP may correspond to the opening OP of FIG. 5.

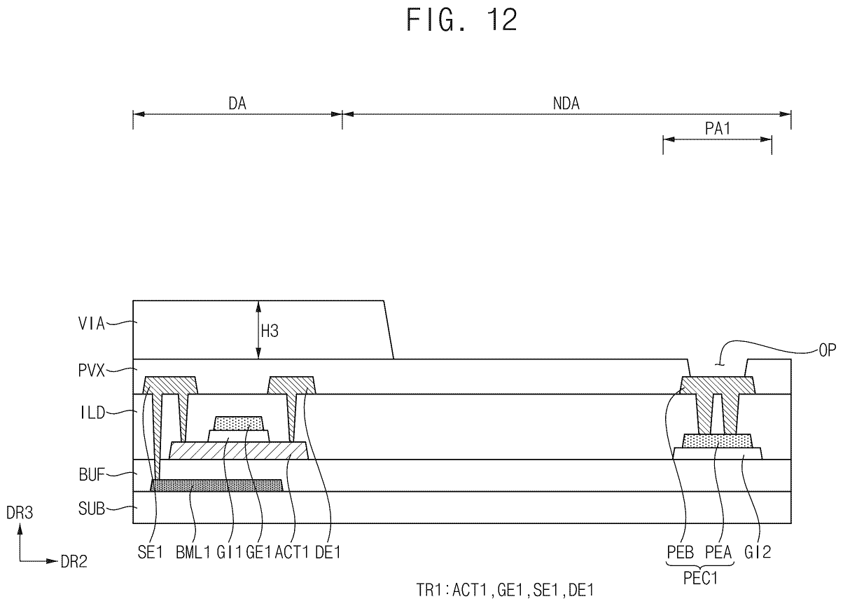

Referring to FIG. 12, at least a portion of the first preliminary via insulating layer (e.g., the first preliminary via insulating layer PVIA1 of FIG. 10) may be removed. In an embodiment, the second portion (e.g., the second portion PVIA-S2 of FIG. 11) of the first preliminary via insulating layer may be entirely removed. A portion of the first portion (e.g., the first portion PVIA-S1 of FIG. 11) of the first preliminary via insulating layer may be removed. In an embodiment, the second portion of the first preliminary via insulating layer and the portion of the first portion of the first preliminary via insulating layer may be removed by a plasma ashing process. For example, the second portion of the first preliminary via insulating layer and the portion of the first portion of the first preliminary via insulating layer may be removed by an oxygen (“O₂”) plasma ashing process. For example, through the plasma ashing process, the second portion of the first preliminary via insulating layer may be completely removed, and the thickness (e.g., the thickness H1 of FIG. 11) of the first portion of the first preliminary via insulating layer may be reduced. Accordingly, the via insulating layer VIA may be formed. A thickness H3 of the via insulating layer VIA in the third direction DR3 may be less than the thickness (e.g., the thickness H1 of FIG. 11) of the first portion of the first preliminary via insulating layer.

In an embodiment, after at least a portion of the first preliminary via insulating layer is removed, plasma treatment may be performed on the passivation layer PVX. For example, nitrogen (“N₂”) plasma treatment may be performed on the passivation layer PVX. As described above, the first preliminary via insulating layer may be removed by an oxygen plasma ashing process. The passivation layer PVX including a nitride such as silicon nitride (“SiNₓ”), silicon oxynitride (“SiOₓN_{y}”) may be oxidized to be converted into an oxygen-rich insulating layer. Accordingly, the passivation layer PVX may be an insulating layer vulnerable to moisture or the like. Accordingly, moisture or the like may penetrate into vicinity of the metals disposed under the passivation layer PVX. According to an embodiment, the passivation layer PVX may be nitrided again by performing the nitrogen plasma treatment on the passivation layer PVX oxidized through the oxygen plasma ashing process. Therefore, moisture or the like may be prevented from penetrating into metals disposed under the passivation layer PVX.

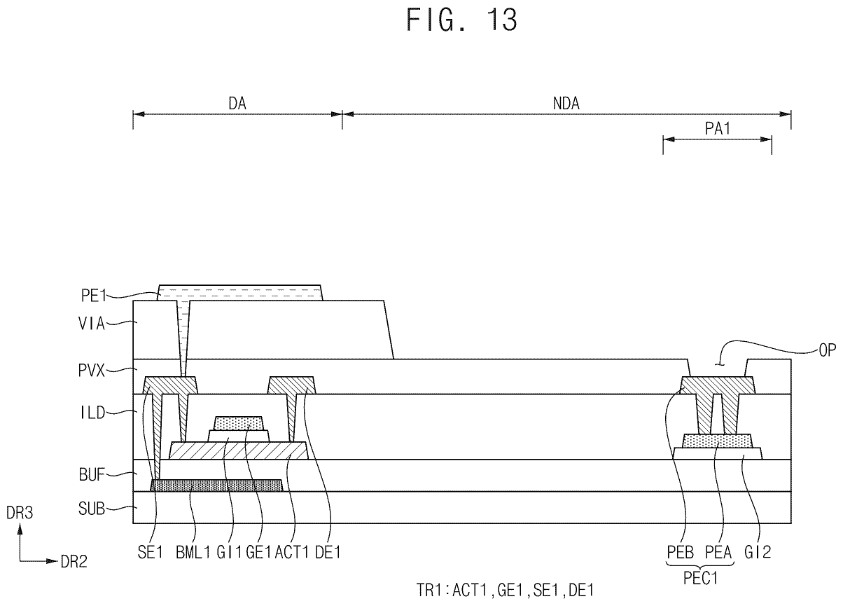

Referring to FIG. 13, the first pixel electrode PE1 may be formed on the via insulating layer VIA. The first pixel electrode PE1 may be formed in the display area DA. A contact hole for connecting the first pixel electrode PE1 and the first contact electrode SE1 may be formed in the via insulating layer VIA and the passivation layer PVX.

For example, the first pixel electrode PE1 may include a metal, an alloy, a metal nitride, a conductive metal oxide, a transparent conductive material, or the like. These materials may be used alone or in combination with each other. In an embodiment, the first pixel electrode PE1 may have a stacked structure including ITO/Ag/ITO. The first pixel electrode PE1 may operate as an anode.

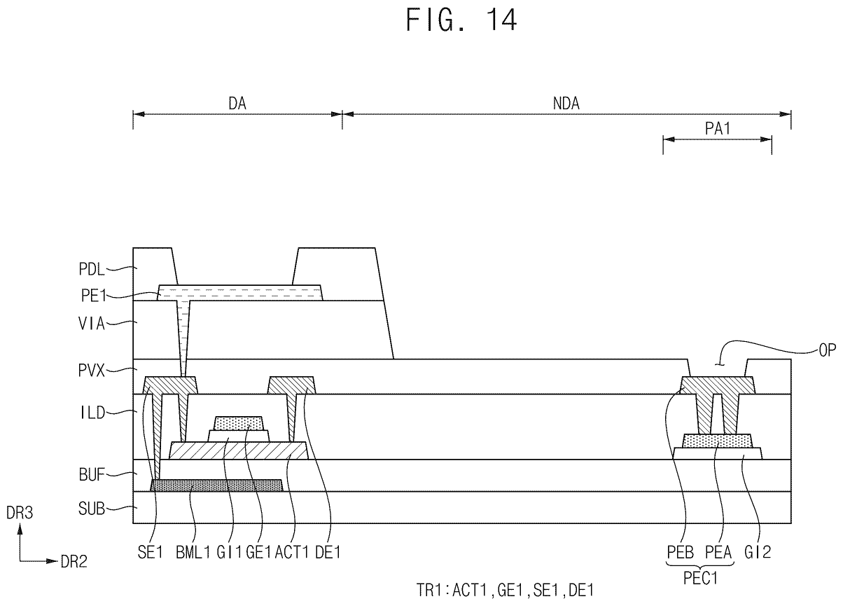

Referring to FIG. 14, the pixel defining layer PDL may be formed on the via insulating layer VIA. The pixel defining layer PDL may be formed to cover the side portion of the first pixel electrode PE1. For example, the pixel opening exposing at least a portion of the upper surface of the first pixel electrode PE1 may be formed in the pixel defining layer PDL.

For example, the pixel defining layer PDL may include an inorganic material or an organic material. In an embodiment, the pixel defining layer PDL may include an organic material such as an epoxy resin or a siloxane resin. These materials may be used alone or in combination with each other. In another embodiment, the pixel defining layer PDL may further include a light blocking material including a black pigment, a black dye, or the like.

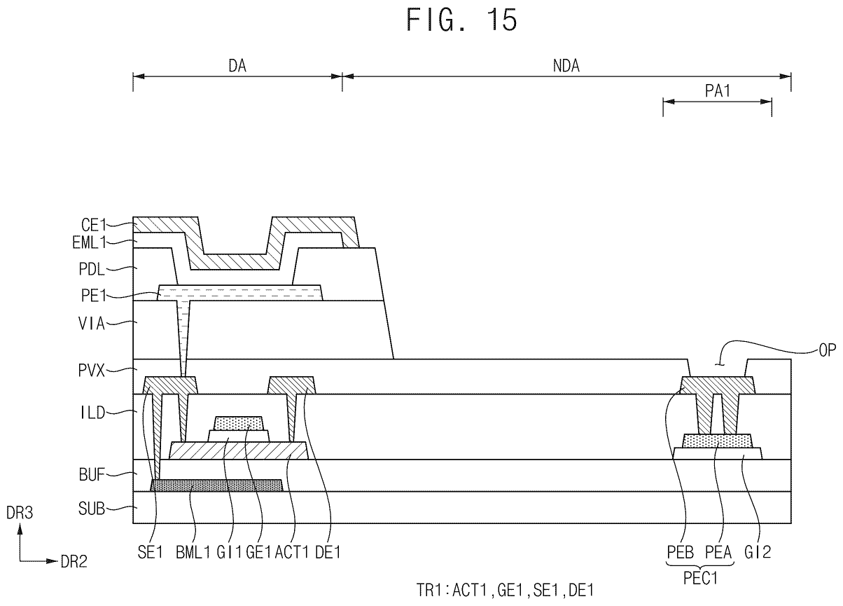

Referring to FIG. 15, the first light emitting layer EML1 may be formed on the first pixel electrode PE1 and the pixel defining layer PDL. The portion of the first light emitting layer EML1 may be formed in the pixel opening of the pixel defining layer PDL. In an embodiment, the first light emitting layer EML1 may include the first functional layer including an organic material, the light emitting layer including a light emitting material, and the second functional layer including an organic material. For example, the first functional layer may include a hole injection layer, a hole transport layer, and the like, and the second functional layer may include an electron transport layer, an electron injection layer, and the like.

The first common electrode CE1 may be formed on the first light emitting layer EML1. The first common electrode CE1 may include a metal, an alloy, a metal nitride, a conductive metal oxide, a transparent conductive material, or the like. These materials may be used alone or in combination with each other. The first common electrode CE1 may operate as a cathode.

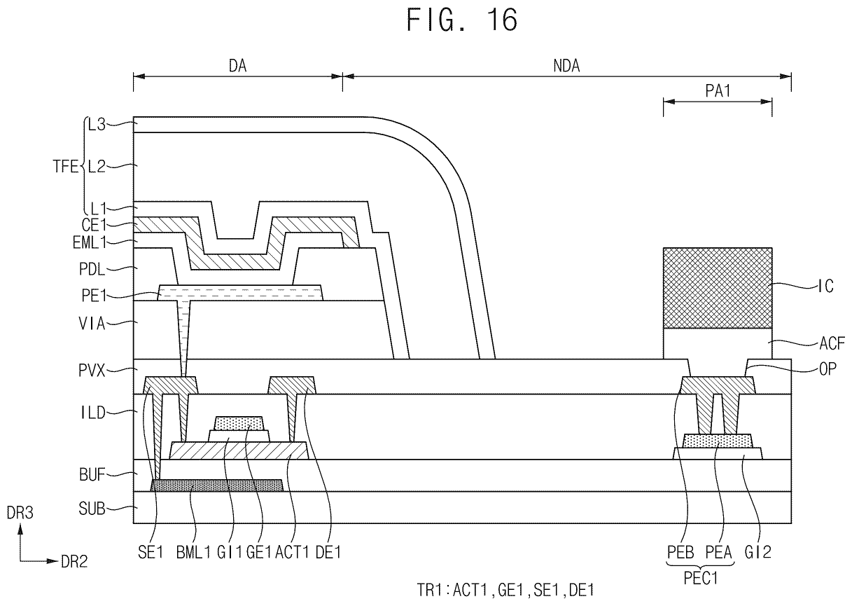

Referring to FIG. 16, the encapsulation layer TFE may be formed on the first common electrode CE1. For example, the first inorganic encapsulation layer L1 covering the first common electrode CE1, the pixel defining layer PDL, and the via insulating layer VIA may be formed. The organic encapsulation layer L2 may be formed on the first inorganic encapsulation layer L1. The second inorganic encapsulation layer L3 may be formed on the organic encapsulation layer L2. Each of the first inorganic encapsulation layer L1 and the second inorganic encapsulation layer L3 may include an inorganic material, and the organic encapsulation layer L2 may include an organic material.

The driving chip IC may be attached to the first pad area PA1. For example, the connection member ACF may be formed in the second opening OP, and the driving chip IC and the first pad electrode PEC1 may be electrically connected through the connection member ACF. For example, the driving chip IC and the second auxiliary pad electrode PEB may be electrically connected through the connection member ACF.

In an embodiment, the connection member ACF may include an anisotropic conductive film. For example, the connection member ACF may include an adhesive layer and conductive particles. Each of the conductive particles may include a core including an insulating polymer material and a conductive layer surrounding the core and including a conductive metal material.

Referring to FIG. 17, the second lower metal pattern BML2, the first lower auxiliary electrode BE1, the second lower auxiliary electrode BE2, the third lower auxiliary electrode BE3 and the fourth lower auxiliary electrode BE4 may be formed on the substrate SUB. The first lower auxiliary electrode BE1, the second lower auxiliary electrode BE2, the third lower auxiliary electrode BE3, and the fourth lower auxiliary electrode BE4 may be formed in the non-display area NDA. The second lower metal pattern BML2 may be formed in the display area DA. For example, the second lower metal pattern BML2 may be formed in a portion of the display area DA adjacent to the non-display area NDA.

For example, each of the second lower metal pattern BML2, the first lower auxiliary electrode BE1, the second lower auxiliary electrode BE2, the third lower auxiliary electrode BE3, and the fourth lower auxiliary electrode BE4 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the second lower metal pattern BML2, the first lower auxiliary electrode BE1, the second lower auxiliary electrode BE2, the third lower auxiliary electrode BE3, and the fourth lower auxiliary electrode BE4 may include substantially the same material and may be formed through a same process.

The buffer layer BUF may be formed on the substrate SUB. The buffer layer BUB may cover the second lower metal pattern BML2, the first lower auxiliary electrode BE1, the second lower auxiliary electrode BE2, the third lower auxiliary electrode BE3, and the fourth lower auxiliary electrode BE4.

The second transistor TR2 may be formed on the substrate SUB. For example, the second active pattern ACT2 may be formed on the buffer layer BUF, the second gate electrode GE2 may be formed on the third gate insulating layer GI3, and the third contact electrode SE2 and the fourth contact electrode DE2 may be formed on the interlayer insulating layer ILD.

The second active pattern ACT2 may be formed on the buffer layer BUF. The second active pattern ACT2 may be formed to at least partially overlap the second lower metal pattern BML2 in a plan view. For example, the second active pattern ACT2 may include an oxide semiconductor material, a silicon semiconductor material, and/or an organic semiconductor material. The second active pattern ACT2 may include the first contact area, the second contact area, and the channel area between the first contact area and the second contact area. The first contact area and the second contact area may have higher conductivity than the channel area.

In an embodiment, the second active pattern ACT2 may include an oxide semiconductor material. However, this disclosure is not limited thereto, and in another embodiment, the second active pattern ACT2 may include a silicon semiconductor material. Examples of the oxide semiconductor material that can be used as the second active pattern ACT2 may include indium gallium zinc oxide (“IGZO”), zinc tin oxide (“ZTO”), indium tin zinc oxide (“ITZO”), or the like. These materials may be used alone or in combination with each other.

The third gate insulating layer GI3 may be formed on the second active pattern ACT2. The third gate insulating layer GI3 may be formed to cover at least a portion of the second active pattern ACT2. For example, the third gate insulating layer GI3 may be formed to cover the upper surface of the second active pattern ACT2.

For example, the third gate insulating layer GI3 may include an inorganic material such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The second gate electrode GE2 may be formed on the third gate insulating layer GI3. The second gate electrode GE2 may overlap the channel area of the second active pattern ACT2 in a plan view. For example, the second gate electrode GE2 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

The interlayer insulating layer ILD may be formed on the second gate electrode GE2. The interlayer insulating layer ILD may be formed to sufficiently cover the second gate electrode GE2.

The first conductive layer CL1, the second conductive layer CL2, the third conductive layer CL3, the fourth conductive layer CL4, the third contact electrode SE2 and the fourth contact electrode DE2 may be formed on the interlayer insulating layer ILD. The first conductive layer CL1, the second conductive layer CL2, the third conductive layer CL3, and the fourth conductive layer CL4 may be formed in the non-display area NDA.

A contact hole for connecting the first conductive layer CL1 and the first lower auxiliary electrode BE1 may be formed in the interlayer insulating layer ILD and the buffer layer BUF. A contact hole for connecting the second conductive layer CL2 and the second lower auxiliary electrode BE2 may be formed in the interlayer insulating layer ILD and the buffer layer BUF. A contact hole for connecting the third conductive layer CL3 and the third lower auxiliary electrode BE3 may be formed in the interlayer insulating layer ILD and the buffer layer BUF. A contact hole for connecting the fourth conductive layer CL4 and the fourth lower auxiliary electrode BE4 may be formed in the interlayer insulating layer ILD and the buffer layer BUF.

The third contact electrode SE2 and the fourth contact electrode DE2 may be formed in the display area DA. A contact hole for connecting the third contact electrode SE2 and the first contact area of the second active pattern ACT2 may be formed in the interlayer insulating layer ILD. A contact hole for connecting the fourth contact electrode DE2 and the second contact area of and the second active pattern ACT2 may be formed in the interlayer insulating layer ILD. A contact hole for connecting the third contact electrode SE2 and the second lower metal pattern BML2 may be formed in the interlayer insulating layer ILD and the buffer layer BUF.

Each of the first conductive layer CL1, the second conductive layer CL2, the third conductive layer CL3, the fourth conductive layer CL4, the third contact electrode SE2, and the fourth contact electrode DE2 may include a conductive material such as a metal, an alloy, a conductive metal oxide, a conductive metal nitride, a transparent conductive oxide, or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other. Examples of the conductive metal oxide may include indium tin oxide, indium zinc oxide, or the like. These materials may be used alone or in combination with each other. Examples of the metal nitride may include aluminum nitride (“AlNₓ”), tungsten nitride (“WNₓ”), chromium nitride (“CrNₓ”), or the like. These materials may be used alone or in combination with each other.

In an embodiment, the first conductive layer CL1, the second conductive layer CL2, the third conductive layer CL3, the fourth conductive layer CL4, the third contact electrode SE2, and the fourth contact electrode DE2 may include substantially the same material and may be formed through a same process.

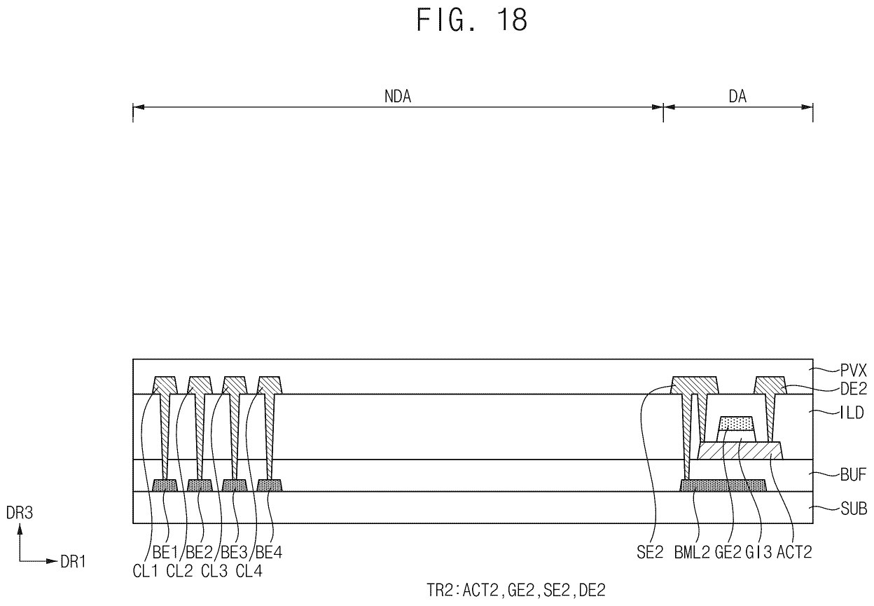

Referring to FIG. 18, the passivation layer PVX may be formed on an interlayer insulating layer ILD. The passivation layer PVX may be formed to cover the first conductive layer CL1, the second conductive layer CL2, the third conductive layer CL3, the fourth conductive layer CL4, the third contact electrode SE2 and the fourth contact electrode DE2. As described above, the passivation layer PVX may be referred to as a first insulating layer.

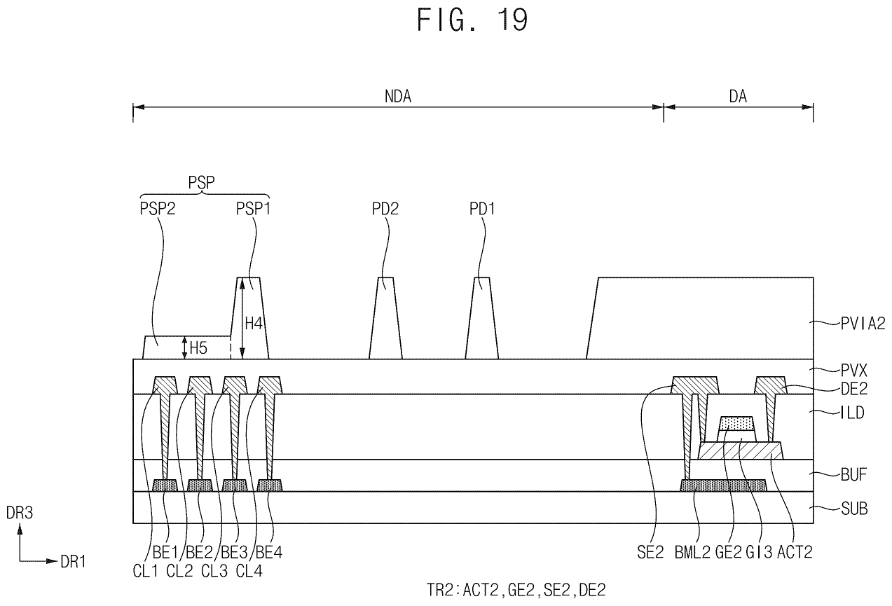

Referring to FIG. 19, a second preliminary via insulating layer PVIA2, a first preliminary dam PD1, a second preliminary dam PD2, and a protecting insulating layer PSP may be formed on the passivation layer PVX. The second preliminary via insulating layer PVIA2 may be formed over the display area DA and the non-display area NDA. The second preliminary via insulating layer PVIA2 may be formed to overlap the second transistor TR2 in a plan view. The first preliminary dam PD1 may be formed outside the second preliminary via insulating layer PVIA2. For example, the first preliminary dam PD1 may be spaced apart from the second preliminary via insulating layer PVIA2 in the direction opposite to the first direction DR1 in a cross-sectional view. The second preliminary dam PD2 may be formed outside the first preliminary dam PD1. For example, the second preliminary dam PD2 may be spaced apart from the first preliminary dam PD1 in the direction opposite to the first direction DR1 in a cross-sectional view. The protecting insulating layer PSP may be formed outside the second preliminary dam PD2. For example, the protecting insulating layer PSP may be spaced apart from the second preliminary dam PD2 in the direction opposite to the first direction DR1 in a cross-sectional view.

In an embodiment, the protecting insulating layer PSP may at least partially overlap multiple conductive layers disposed on the interlayer insulating layer ILD in a plan view. For example, the protecting insulating layer PSP may overlap the first conductive layer CL1, the second conductive layer CL2, the third conductive layer CL3, and the fourth conductive layer CL4 in a plan view. However, this disclosure is not limited thereto, and in another embodiment, the protecting insulating layer PSP may overlap only some of the conductive layers in a plan view. For example, the protecting insulating layer PSP may overlap the second conductive layer CL2, the third conductive layer CL3, and the fourth conductive layer CL4 in a plan view, and may not overlap the first conductive layer CL1 in a plan view.

In an embodiment, the protecting insulating layer PSP may include a first portion PSP1 and a second portion PSP2. The second portion PSP2 may be in contact with the first portion PSP1 in the direction opposite to the first direction DR1 in a cross-sectional view. In an embodiment, a thickness H4 of the first portion PSP1 may be greater than a thickness H5 of the second portion PSP2. For example, the thickness H4 of the first portion PSP1 in the third direction DR3 may be greater than the thickness H5 of the second portion PSP2 in the third direction DR3. In an embodiment, the thickness H4 of the first portion PSP1, a thickness of the second preliminary via insulating layer PVIA2, a thickness of the first preliminary dam PD1, and a thickness the second preliminary dam PD2 in the third direction DR3 may be substantially the same.

For example, the protecting insulating layer PSP including the first portion PSP1 and the second portion PSP2 may be formed through a halftone mask including a light transmitting area and a semi-light transmitting area. For example, the semi-transmitting area may be an area through which light is transmitted through the halftone mask, the semi-transmitting area may be an area through which light in an amount less than light passing through the transmitting area is transmitted through the halftone mask.

For example, each of the second preliminary via insulating layer PVIA2, the first preliminary dam PD1, the second preliminary dam PD2, and the protecting insulating layer PSP may include an organic material. For example, each of the second preliminary via insulating layer PVIA2, the first preliminary dam PD1, the second preliminary dam PD2, and the protecting insulating layer PSP may include an organic material such as a phenolic resin, a polyacrylate resin, a polyimide resin, a polyamide resin, a siloxane resin, an epoxy resin, or the like. These materials may be used alone or in combination with each other.

In an embodiment, the second preliminary via insulating layer PVIA2, the first preliminary dam PD1, the second preliminary dam PD2, and the protecting insulating layer PSP may include substantially the same material and may be formed through a same process. For example, the second preliminary via insulating layer PVIA2, the first preliminary dam PD1, the second preliminary dam PD2, and the protecting insulating layer PSP may be formed simultaneously.

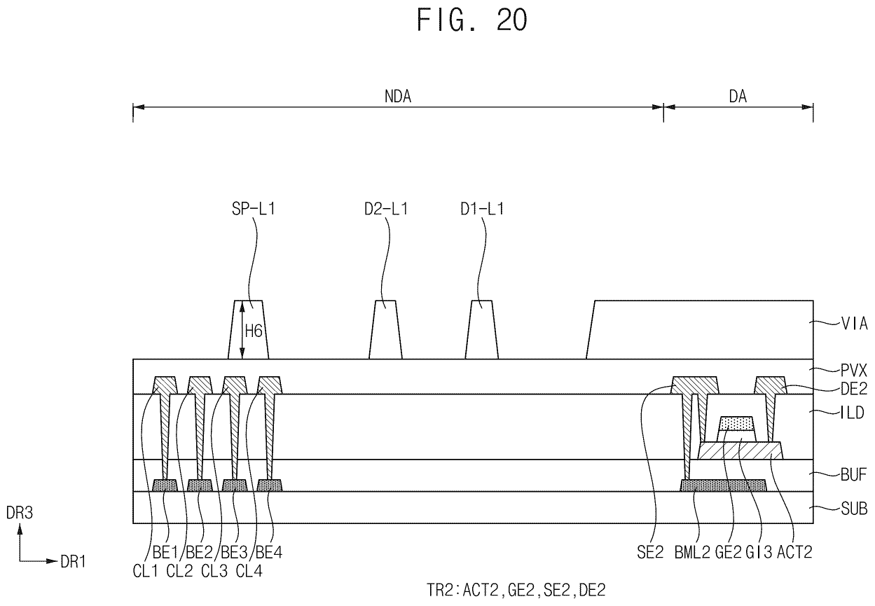

Referring to FIGS. 19 and 20, at least a portion of the protecting insulating layer PSP may be removed. In an embodiment, the second portion PSP2 of the protective insulating layer PSP may be removed. The second portion PSP2 may be entirely removed. At least a portion of the first portion PSP1 may be removed. A portion of the first preliminary dam PD1, the second preliminary dam PD2, and the second preliminary via insulating layer PVIA2 may be removed. In an embodiment, a portion of the first portion PSP1, a portion of the first preliminary dam PD1, a portion of the second preliminary dam PD2, a portion of the second preliminary via insulating layer PVIA2, and the second portion PSP2 may be removed by a plasma ashing process. For example, the portion of the first portion PSP1, the portion of the first preliminary dam PD1, the portion of the second preliminary dam PD2, the portion of the second preliminary via insulating layer PVIA2, and the second portion PSP2 may be removed by an oxygen plasma ashing process. For example, through the plasma ashing process, the second portion PSP2 may be completely removed, and the thickness H4 of the first portion PSP1 may be reduced. Through the plasma ashing process, the thickness of the first preliminary dam PD1, the thickness of the second preliminary dam PD2, and the thickness of the second preliminary via insulating layer PVIA2 may be reduced. Accordingly, the first layer SP-L1 of the support part (e.g., the support part SP of FIG. 6) and the first layer D1-L1 of the first dam (e.g., the first dam D1 of FIG. 6) and the second layer D2-L1 of the second dam (e.g., the second dam D2 of FIG. 6) and the via insulating layer VIA may be formed.

A thickness H6 of the first layer SP-L1 of the support part in the third direction DR3 may be less than the thickness H4 of the first portion PSP1.

When the plasma ashing process is performed, the passivation layer PVX including

a nitride such as silicon nitride (“SiNₓ”), silicon oxynitride (“SiOₓN_{y}”) may be oxidized to be converted into an oxygen-rich insulating layer. Accordingly, the passivation layer PVX may be an insulating layer vulnerable to moisture, or the like and insulating layers disposed on the passivation layer PVX such as the support part may be lifted. Accordingly, moisture or the like may penetrate into vicinity of the metals disposed under the passivation layer PVX. For example, moisture or the like may penetrate near the first conductive layer CL1, the second conductive layer CL2, the third conductive layer CL3, and the fourth conductive layer CL4, and parasitic capacitance may be formed near the first conductive layer CL1, the second conductive layer CL2, the third conductive layer CL3, and the fourth conductive layer CL4. As described above, the clock signal may be applied through the first conductive layer CL1, the second conductive layer CL2, the third conductive layer CL3, and the fourth conductive layer CL4. In case that moisture or the like penetrates into the vicinity of the first conductive layer CL1, the second conductive layer CL2, the third conductive layer CL3, and the fourth conductive layer CL4, the clock signal may be applied to the first conductive layer CL1, the second conductive layer CL2, the third conductive layer CL3, and the fourth conductive layer CL4 with delay. Accordingly, the gate driver (e.g., the gate driver 200 of FIG. 4) may output an abnormal signal. Accordingly, a problem in which horizontal lines are visually recognized in the display area (e.g., the display area DA of FIG. 1) may occur.

According to an embodiment, the protecting insulating layer PSP may be formed in a portion overlapping the first conductive layer CL1, the second conductive layer CL2, the third conductive layer CL3, and the fourth conductive layer CL4 on the passivation layer PVX in a plan view. For example, the first portion PSP1 may be formed to overlap the third conductive layer CL3 and the fourth conductive layer CL4 in a plan view, and the second portion PSP2 may be formed to overlap the first conductive layer CL1 and the second conductive layer CL2 in a plan view. Accordingly, the protecting insulating layer PSP may prevent a portion of the passivation layer PVX covering the first conductive layer CL1, the second conductive layer CL2, the third conductive layer CL3, and the fourth conductive layer CL4 from being converted into an oxygen-rich insulating layer during the plasma ashing process. Therefore, moisture or the like may not penetrate into the vicinity of the first conductive layer CL1, the second conductive layer CL2, the third conductive layer CL3, and the fourth conductive layer CL4. Accordingly, the parasitic capacitance may be prevented from being generated in the vicinity of the first conductive layer CL1, the second conductive layer CL2, the third conductive layer CL3, and the fourth conductive layer CL4. Accordingly, a phenomenon in which the clock signal is applied to the first conductive layer CL1, the second conductive layer CL2, the third conductive layer CL3, and the fourth conductive layer CL4 with delay may be prevented, and the gate driver may output a normal signal to the display area. Accordingly, the horizontal lines may not be visible to the display area.

After the plasma ashing process, a plasma treatment may be performed on the passivation layer PVX. For example, a nitrogen (“N₂”) plasma treatment may be performed on the passivation layer PVX. The passivation layer PVX may be oxidized by the plasma ashing process in a portion where the protecting insulating layer PSP, the first preliminary dam PD1, the second preliminary dam PD2, and the second preliminary via insulating layer PVIA2 are not disposed. Accordingly, the passivation layer PVX may be nitrided again by performing the nitrogen plasma treatment on the oxidized passivation layer PVX.

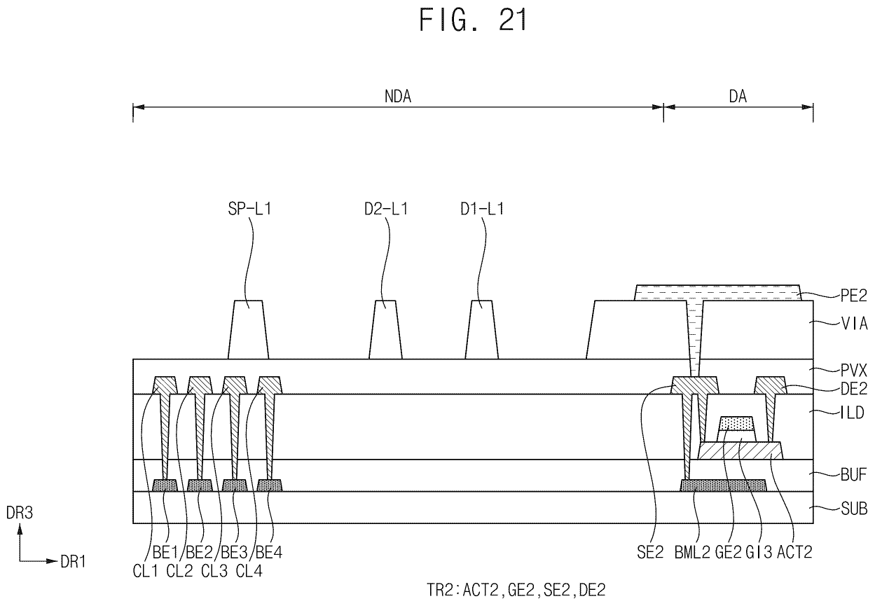

Referring to FIG. 21, the second pixel electrode PE2 may be formed on the via insulating layer VIA. The second pixel electrode PE2 may be formed in the display area DA. A contact hole for connecting the second pixel electrode PE2 and the third contact electrode SE2 may be formed in the via insulating layer VIA and the passivation layer PVX.

For example, the second pixel electrode PE2 may include a metal, an alloy, a metal nitride, a conductive metal oxide, a transparent conductive material, or the like. These materials may be used alone or in combination with each other. In an embodiment, the second pixel electrode PE2 may have a stacked structure including ITO/Ag/ITO. The second pixel electrode PE2 may operate as an anode.

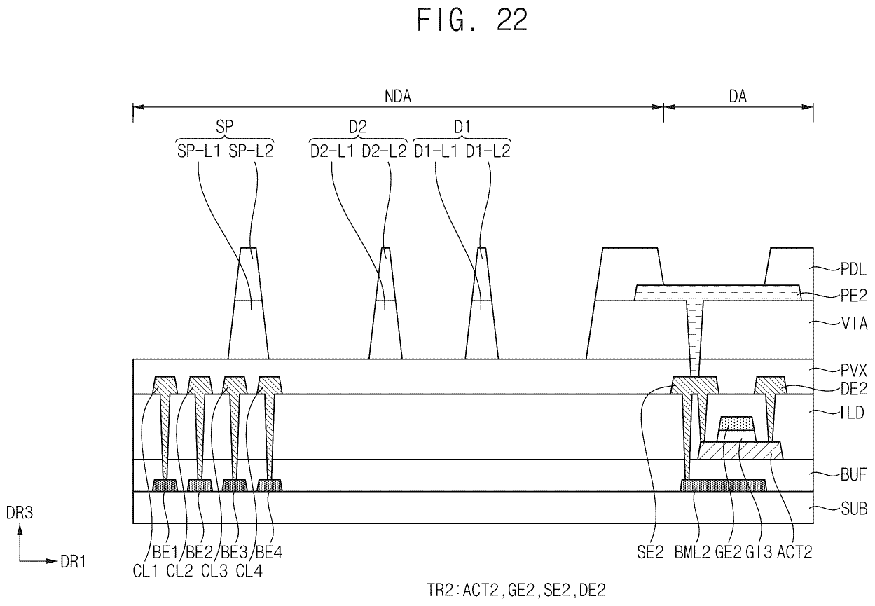

Referring to FIG. 22, the pixel defining layer PDL may be formed on the via insulating layer VIA. The pixel defining layer PDL may be formed to cover the side portion of the second pixel electrode PE2. For example, the pixel opening exposing at least a portion of the upper surface of the second pixel electrode PE2 may be formed in the pixel defining layer PDL.

For example, the pixel defining layer PDL may include an inorganic material or an organic material. In an embodiment, the pixel defining layer PDL may include an organic material such as an epoxy resin, a siloxane resin or the like. These materials may be used alone or in combination with each other. In another embodiment, the pixel defining layer PDL may further include a light blocking material including a black pigment, a black dye, or the like.

The second layer D1-L2 may be formed on the first layer D1-L1 of the first dam D1. The second layer D2-L2 may be formed on the first layer D2-L1 of the second dam D2. The second layer SP-L2 may be formed on the first layer SP-L1 of the support part SP. The second layer D1-L2 of the first dam D1, the second layer D2-L2 of the second dam D2, the second layer SP-L2 of the support part SP, and the pixel defining layer PDL may include substantially the same material and may be formed through a same process.

For example, the second layer D1-L2 may be formed on the first layer D1-L1 to form the first dam D1. The second layer D2-L2 may be formed on the first layer D2-L1 to form the second dam D2. The second layer SP-L2 may be formed on the first layer SP-L1 to form the support part SP. For example, the second layer SP-L2 of the support part SP may be referred to as a third insulating layer.

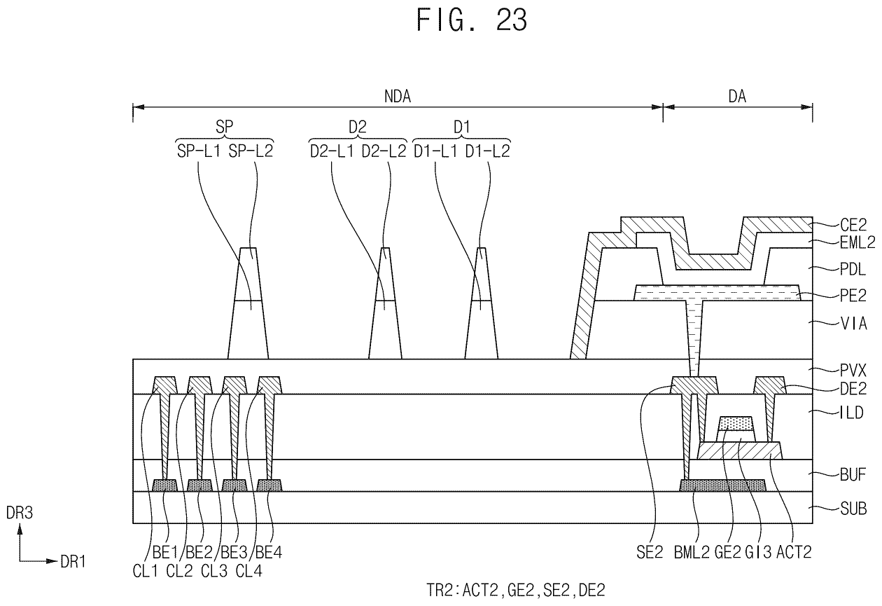

Referring to FIG. 23, the second light emitting layer EML2 may be formed on the second pixel electrode PE2 and the pixel defining layer PDL. The portion of the second light emitting layer EML2 may be disposed in the pixel opening of the pixel defining layer PDL. In an embodiment, the second light emitting layer EML2 may include the first functional layer including an organic material, the light emitting layer including a light emitting material, and the second functional layer including an organic material disposed on the light emitting layer. For example, the first functional layer may include a hole injection layer, a hole transport layer, and the like and the second functional layer may include an electron transport layer, an electron injection layer, and the like.

The second common electrode CE2 may be formed on the second light emitting layer EML2. The second common electrode CE2 may include a metal, an alloy, a metal nitride, a conductive metal oxide, a transparent conductive material, or the like. These materials may be used alone or in combination with each other. The second common electrode CE2 may operate as a cathode.

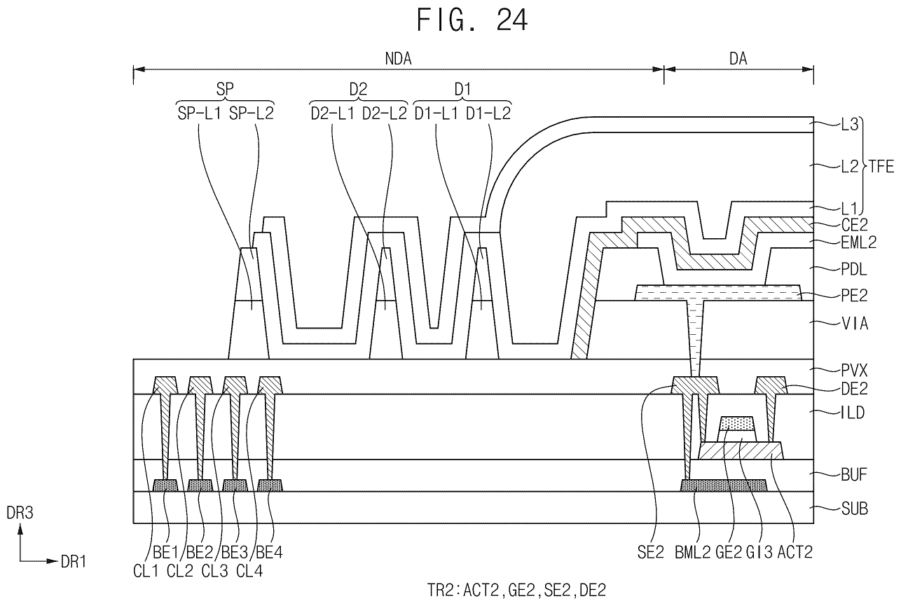

Referring to FIG. 24, The encapsulation layer TFE may be formed on the second common electrode CE2. For example, the first inorganic encapsulation layer L1 covering the second common electrode CE2, the pixel defining layer PDL, and the via insulating layer VIA may be formed. The organic encapsulation layer L2 may be formed on the first inorganic encapsulation layer L1. The second inorganic encapsulation layer L3 may be formed on the organic encapsulation layer L2. Each of the first inorganic encapsulation layer L1 and the second inorganic encapsulation layer L3 may include an inorganic material, and the organic encapsulation layer L2 may include an organic material.

The encapsulation layer TFE may be formed over the entire display area DA and the non-display area NDA. For example, the first inorganic encapsulation layer L1 and the second inorganic encapsulation layer L3 may cover the display area DA and may extend to an outside of the second dam D2. In an embodiment, the first inorganic encapsulation layer L1 and the second inorganic encapsulation layer L3 may extend to an upper surface of the support part SP.

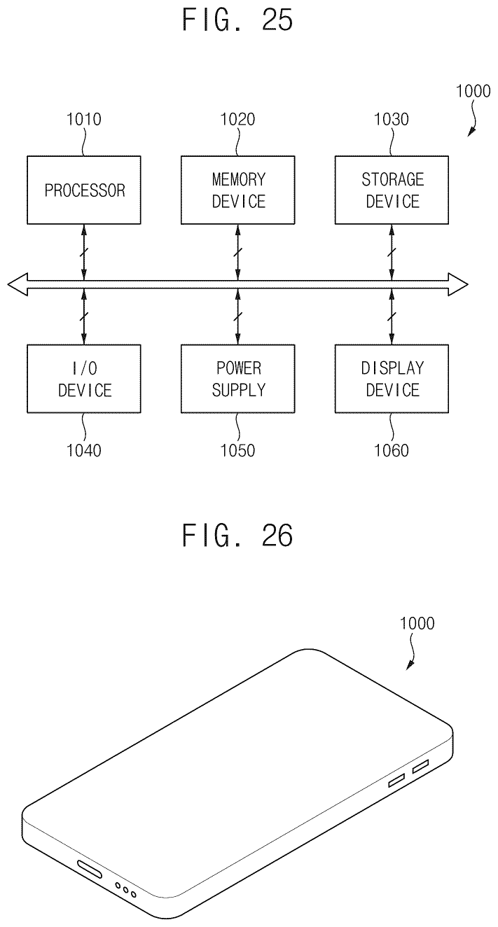

FIG. 25 is a block diagram illustrating an electronic device according to embodiments. FIG. 26 is a diagram illustrating an example in which the electronic device of FIG. 25 is implemented as a smart phone.

Referring to FIGS. 25 and 26, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 26, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The disclosure may be applied to various display devices. For example, the disclosure may be applicable to various display devices such as display devices for vehicles, ships and aircraft, portable communication devices, display devices for exhibition or information transmission, medical display devices, and the like.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A method of manufacturing a display device, the method comprising:
forming a transistor on a substrate including a display area and a non-display area surrounding at least a portion of the display area;
forming a first conductive layer in the non-display area on the substrate;
forming a first insulating layer covering the first conductive layer and the transistor;
forming a protecting insulating layer at least partially overlapping the first conductive layer in a plan view on the first insulating layer, the protecting insulating layer including a first portion and a second portion having a thickness smaller than a thickness of the first portion;
forming a second insulating layer at least partially overlapping the transistor in a plan view on the first insulating layer;
removing the second portion of the protecting insulating layer;
forming a first electrode connected to the transistor on the second insulating layer;
forming a pixel defining layer covering a side portion of the first electrode on the second insulating layer;
forming a light emitting layer on the first electrode; and
forming a second electrode on the light emitting layer.

2. The method of claim 1, wherein the removing of the second portion of the protecting insulating layer is performed through a plasma ashing process.

3. The method of claim 1, further comprising:
forming a preliminary dam in the non-display area on the first insulating layer,
wherein the forming of the protecting insulating layer and the forming of the preliminary dam are performed simultaneously.

4. The method of claim 1, wherein the first conductive layer is disposed in a gate driver disposed in the non-display area on the substrate.

5. The method of claim 4, wherein a clock signal is applied through the first conductive layer.

6. The method of claim 1, further comprising:
forming a second conductive layer spaced apart from the first conductive layer in a plan view in the non-display area on the substrate, the first conductive layer and the second conductive layer disposed on a same layer, and the second conductive layer applied with a clock signal.

7. The method of claim 1, further comprising:
performing plasma treatment on the first insulating layer after the removing of the second portion of the protecting insulating layer. 00 The method of claim 7, wherein the performing of plasma treatment on the first insulating layer is performing nitrogen (N₂) plasma treatment on the first insulating layer.

9. The method of claim 1, wherein through the removing of the second portion of the protecting insulating layer, a thickness of the first portion of the protecting insulating layer is reduced.

10. The method of claim 9, further comprising:
forming a third insulating layer on the first portion of the protecting insulating layer with a reduced thickness to form a support part including the first portion with the reduced thickness and the third insulating layer.

11. The method of claim 1, wherein
the non-display area includes a pad area, and
the method further comprises:
forming a first auxiliary pad electrode in the pad area on the substrate; and
forming a second auxiliary pad electrode on the first auxiliary pad electrode.

12. The method of claim 11, wherein the forming of the first insulating layer includes:
forming a first preliminary insulating layer covering the second auxiliary pad electrode; and
forming a first opening exposing an upper surface of the second auxiliary pad electrode in the first preliminary insulating layer.

13. The method of claim 12, wherein the forming of the first opening in the first preliminary insulating layer includes:
forming a second preliminary insulating layer on the first preliminary insulating layer;
forming a second opening overlapping the second auxiliary pad electrode in a plan view in the second preliminary insulating layer; and
forming the first opening overlapping the second opening in a plan view in the first preliminary insulating layer.

14. The method of claim 13, further comprising:
removing at least a portion of the second preliminary insulating layer after the forming of the first opening.

15. A method of manufacturing a display device, the method comprising:
forming a transistor on a substrate including a display area and a non-display area surrounding at least a portion of the display area;
forming a conductive layer in the non-display area on the substrate;
forming a passivation layer covering the conductive layer and the transistor;
forming a protecting insulating layer at least partially overlapping the conductive layer in a plan view on the passivation layer, the protecting insulating layer including a first portion and a second portion having a thickness smaller than a thickness of the first portion;
forming a via insulating layer at least partially overlapping the transistor in a plan view on the passivation layer;
removing the second portion of the protecting insulating layer;
forming a pixel electrode connected to the transistor on the via insulating layer;
forming a pixel defining layer covering a side portion of the pixel electrode on the via insulating layer;
forming a light emitting layer on the pixel electrode; and
forming a common electrode on the light emitting layer.

16. The method of claim 15, wherein the removing of the second portion of the protecting insulating layer is performed through a plasma ashing process.

17. The method of claim 15, further comprising:
forming a preliminary dam in the non-display area on the passivation layer,
wherein the forming of the protecting insulating layer and the forming of the preliminary dam are performed simultaneously.

18. The method of claim 15, wherein the conductive layer is disposed in a gate driver disposed in the non-display area on the substrate.

19. The method of claim 18, wherein a clock signal is applied through the conductive layer.

20. The method of claim 15, further comprising:
performing plasma treatment on the passivation layer after the removing of the second portion of the protecting insulating layer.

21. An electronic device, comprising:
a display device; and
a memory device configured to store data,
wherein a method of manufacturing the display device includes:
forming a transistor on a substrate including a display area and a non-display area surrounding at least a portion of the display area;
forming a first conductive layer in the non-display area on the substrate;
forming a first insulating layer covering the first conductive layer and the transistor;
forming a protecting insulating layer at least partially overlapping the first conductive layer in a plan view on the first insulating layer, the protecting insulating layer including a first portion and a second portion having a thickness smaller than a thickness of the first portion;
forming a second insulating layer at least partially overlapping the transistor in a plan view on the first insulating layer;
removing the second portion of the protecting insulating layer;
forming a first electrode connected to the transistor on the second insulating layer;
forming a pixel defining layer covering a side portion of the first electrode on the second insulating layer;
forming a light emitting layer on the first electrode; and
forming a second electrode on the light emitting layer.
